(19) United States
(12) Patent Application Publication
(10) Pub. No.: US 2024/0288498 A1
(43) Pub. Date: Aug. 29, 2024

(54) STORAGE BATTERY DIAGNOSIS DEVICE AND STORAGE BATTERY SYSTEM

(71) Applicant: Mitsubishi Electric Corporation, Tokyo (JP)

(72) Inventor: Tomoki TAKEGAMI, Tokyo (JP)

(73) Assignee: Mitsubishi Electric Corporation, Tokyo (JP)

(21) Appl. No.: 18/289,897

(22) PCT Filed: May 13, 2021
(86) PCT No.: PCT/JP2021/018216

§ 371 Date: Nov. 8, 2023

(51) Int. Cl. G01R 31/367; G01R 31/392

(52) U.S. Cl. CPC G01R 31/367; G01R 31/392

(57) ABSTRACT

The storage battery diagnosis device includes: a data point sequence generation unit which generates, on the basis of a current of a storage battery detected by a current detection device and a voltage detected by a voltage detection device, a data point sequence including a Z^{th}-order derivative/integral curve expressed with a Z^{th}-order derivative/integral voltage or a Z^{th}-order derivative/integral capacity where Z represents a real number; a reference data provision unit which provides, as a reference, a reference data point sequence of the storage battery or an electrode; a point set registration unit which performs point set registration between the reference data point sequence and the data point sequence generated by the data point sequence generation unit; and a diagnosis unit which estimates a parameter indicating a state of degradation of the storage battery or the electrode on the basis of a result from the point set registration unit.

### TECHNICAL FIELD

The present disclosure relates to a storage battery diagnosis device and a storage battery system.

### BACKGROUND ART

Electrically-driven vehicles such as electric vehicles (EVs), hybrid electric vehicles (HEVs), and plug-in hybrid vehicles (PHVs) have been put into practical use in order to decrease the burden on the environment. Further, development of electrically-driven aircrafts and the like has also been progressing. In addition, stationary-installation-type power storage systems for utilizing renewable energy have also become widespread.

In these apparatuses, storage batteries such as lithium-ion batteries have been used. It is known that, in association with use of such storage batteries, degradation of the storage batteries progresses and the performances thereof decrease. Therefore, in order to ascertain the performance of or the replacement timing for a storage battery and predict the lifespan thereof, it is necessary to perform a degradation diagnosis on the storage battery.

As a method for performing a non-destructive degradation diagnosis on a storage battery, a derivative curve analysis method that involves use of a derivative voltage obtained by differentiating a voltage with a capacity or a derivative capacity obtained by differentiating a capacity with a voltage is known. This degradation diagnosis method is intended to, by utilizing a characteristic that the voltage of a storage battery is expressed with synthesis of the potentials of a positive electrode and a negative electrode, perform a diagnosis regarding various degradation modes on the basis of the heights, the positions, the positional relationship, and the like of feature points (a local maximum point, a local minimum point, an inflection point, and the like) with a curve shape feature being made more distinct through differentiation. In general, the heights, the positions, the positional relationship, and the like of the feature points on derivative voltage curves of the respective positive and negative electrodes change according to degradation in association with use of the storage battery. Therefore, comparison between any feature point of certain reference data and the corresponding feature point of acquired data enables a degradation diagnosis of the storage battery (see, for example, Patent Document 1).

A secondary battery system described in Patent Document 1 includes a determination means for determining whether or not arrival at a certain feature point has occurred on an acquired derivative voltage curve or an acquired derivative capacity curve. The secondary battery system performs diagnoses such as a diagnosis in which, if arrival at the certain feature point is determined to have occurred, a reference power storage amount at the feature point is corrected on the basis of an estimated power storage amount.

In addition, the secondary battery system performs diagnoses such as a diagnosis in which, if charging data is determined to have arrived at a plurality of feature points, a reference value is corrected on the basis of an estimated value regarding the difference in power storage amount between two certain feature points.

### CITATION LIST

### Patent Document

Patent Document 1: Japanese Laid-Open Patent Publication No. 2009-252381

### SUMMARY OF THE INVENTION

### Problem to be Solved by the Invention

However, in a diagnosis performed according to feature points and based on the derivative curve analysis method as in the secondary battery system described in Patent Document 1, it is not easy to determine whether or not arrival at the certain feature point has occurred. In other words, in said diagnosis, it is not easy to accurately ascertain the correspondence relationship between any feature point of the reference data and the corresponding feature point of the acquired data.

Examples of the reason for this include the fact that the positions and the heights of feature points on a voltage curve and a derivative voltage curve of a storage battery change in association with degradation thereof. The following fact is known. That is, in many cases, when an electrode degrades, the distribution of the concentration of lithium-ions inside the electrode increases, and, for this reason and other reasons, the peak shape of a derivative voltage curve becomes gentle. If the degradation progresses, it is also possible that a feature point on the derivative voltage curve vanishes.

In addition, owing to dependence on the rate of charging/discharging current, a temperature, a charging/discharging history, and the like, the position and the height of each feature point could fluctuate even at the same extent of degradation.

In addition, owing to influence of a measurement error and/or a quantization error, a feature point that should be absent could be erroneously detected, and furthermore, the detected feature point itself could have an error. In particular, if differential calculation is included, the error is amplified, and thus this tendency becomes prominent. Meanwhile, there is also a non-detection risk that a feature point vanishes owing to smoothing processing for decreasing error, and a feature point to be detected cannot be detected.

In addition, during actual use of a storage battery, there are many cases where only partial charging data within a limited range of states of charge (SOC) can be obtained. This could also lead to a situation in which a feature point desired to be acquired cannot easily be acquired.

In addition, in an actual use environment, the present SOC itself of a target storage battery includes an estimation error in many cases as well, and thus, if determination as to whether or not the detected feature point is the certain feature point is performed by using the SOC as a reference, the determination might fail.

The present disclosure has been made to solve the above problems, and an object of the present disclosure is to provide a storage battery diagnosis device that can accurately ascertain the correspondence relationship between any feature point of reference data and the corresponding feature point of acquired data and that can perform a highly accurate degradation diagnosis on a storage battery.

### Means to Solve the Problem

A storage battery diagnosis device according to the present disclosure includes:
a data point sequence generation unit which generates, on the basis of a current of a storage battery detected by a current detection device and a voltage of the storage battery detected by a voltage detection device, a data point sequence including a Z^{th}-order derivative/integral curve expressed with a Z^{th}-order derivative/integral voltage or a Z^{th}-order derivative/integral capacity where Z represents a real number;
a reference data provision unit which provides, as a reference, a reference data point sequence of the storage battery or an electrode;
a point set registration unit which performs point set registration between the reference data point sequence and the data point sequence generated by the data point sequence generation unit; and
a diagnosis unit which estimates a parameter indicating a state of degradation of the storage battery or the electrode on the basis of a result from the point set registration unit.

### Effect of the Invention

In the storage battery diagnosis device according to the present disclosure, since point set registration is performed, the correspondence relationship between a generated data point sequence and reference data can be accurately ascertained, and a highly accurate degradation diagnosis can be performed on a storage battery.

### BRIEF DESCRIPTION OF THE DRAWINGS

FIG. 1 is a configuration diagram of a storage battery diagnosis device according to embodiment 1.

FIG. 2 is a hardware configuration diagram of a controller of the storage battery diagnosis device according to embodiment 1.

FIG. 3 explains how degradation modes of a storage battery are classified.

FIG. 4 is a characteristic graph showing an example of a potential curve and a derivative potential curve of an NMC-based positive electrode of a lithium-ion battery including the positive electrode and a graphite negative electrode.

FIG. 5 is a characteristic graph showing an example of a potential curve and a derivative potential curve of the graphite negative electrode of the lithium-ion battery including the NMC-based positive electrode and the negative electrode.

FIG. 6 is a flowchart of a diagnosis in the case of employing ICP in the storage battery diagnosis device according to embodiment 1.

FIG. 7 shows a voltage, and feature points on a first-order derivative voltage and a second-order derivative voltage, of a degraded cell.

FIG. 8 shows feature points on a sigmoid curve, and a first-order derivative curve and a second-order derivative curve of the sigmoid curve.

FIG. 9 shows a voltage, and feature points on a first-order derivative voltage and a second-order derivative voltage, of a new cell.

FIG. 10 is a flowchart of one-dimensional ICP according to embodiment 1.

FIG. 11 shows changes in the RMSEs of results of point set registration performed through the one-dimensional ICP.

FIG. 12 shows comparison between reference data and estimation parameters.

FIG. 13 shows results of estimating positive electrode parameters through repetitive calculation according to a nonlinear optimization method.

FIG. 14 shows estimation results regarding the positive electrode and the negative electrode of each of the new cell and the degraded cell which have been fully charged, and regarding the cells, the estimation being performed by the storage battery diagnosis device according to embodiment 1.

FIG. 15 shows partial charging data, and feature points on a first-order derivative curve and a second-order derivative curve, of the storage battery.

FIG. 16 explains a result of performing point set registration through the one-dimensional ICP.

FIG. 17 shows estimation results regarding the positive electrode and the negative electrode of each of the new cell and the degraded cell which have been partially charged, and regarding the cells, the estimation being performed by the storage battery diagnosis device according to embodiment 1.

FIG. 18 is a flowchart showing an example of a procedure of processing performed through a storage battery diagnosis method according to embodiment 1.

FIG. 19 is a schematic diagram of a storage battery system in which the storage battery diagnosis device according to the embodiment is used.

### DESCRIPTION OF EMBODIMENTS

Hereinafter, a storage battery diagnosis device according to an embodiment for carrying out the present disclosure will be described in detail with reference to the drawings. The same or corresponding constituents in the drawings are denoted by the same reference characters.

### Embodiment 1

### Description of Schematic Overall Configuration

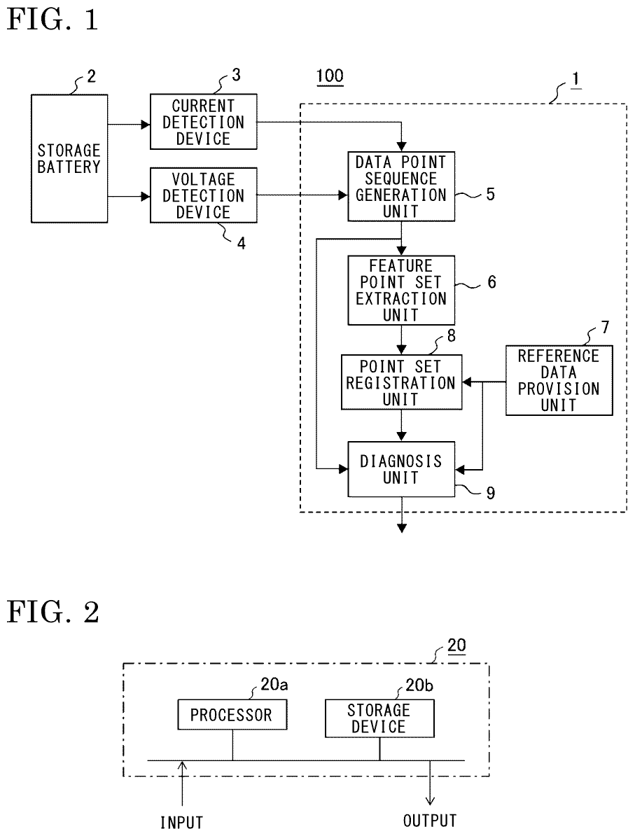

FIG. 1 shows an example of the configuration of a storage battery diagnosis system 100 including a storage battery diagnosis device 1 according to embodiment 1. As shown in FIG. 1, the storage battery diagnosis system 100 includes the storage battery diagnosis device 1, a storage battery 2, a current detection device 3, and a voltage detection device 4.

The storage battery diagnosis device 1 is a device that performs a diagnosis on the storage battery 2. The diagnosis refers to a concept encompassing a diagnosis of the performance, the internal state, or the state of degradation of the storage battery 2 and also encompassing, for example, estimation of: the SOC and the capacity of the storage battery 2, or the extent and the progress level of degradation of the storage battery 2; the extent of decrease in the full charge capacity of the storage battery 2; and a degradation parameter serving as an index of the extent of degradation of the storage battery 2.

The storage battery 2 to be subjected to a diagnosis may be a lithium-ion battery or may be, instead of a lithium-ion battery, a lead storage battery, a nickel-hydrogen storage battery, an all-solid storage battery, or the like. Also, the storage battery 2 to be subjected to a diagnosis may be a single-cell storage battery or may be, instead of a single-cell storage battery, a storage battery module having a plurality of cells connected in series or a storage battery module having a plurality of cells connected in parallel.

An example of the lithium-ion battery to be subjected to a diagnosis is a lithium-ion battery in which a positive electrode is made from a nickel-manganese-cobalt (NMC)-based material and a negative electrode is made from graphite. In addition to an other-material-based lithium-ion battery, a general storage battery that has a positive electrode and a negative electrode and that is capable of charging and discharging may be included.

### Configuration of Storage Battery Diagnosis Device

Next, the configuration of the storage battery diagnosis device 1 according to embodiment 1 will be described with reference to FIG. 1 and FIG. 2. FIG. 2 is a block diagram showing an example of the hardware configuration in the storage battery diagnosis device 1 according to embodiment 1.

As shown in FIG. 1, the storage battery diagnosis device 1 includes a data point sequence generation unit 5, a feature point set extraction unit 6, a reference data provision unit 7, a point set registration unit 8, and a diagnosis unit 9.

FIG. 2 shows an example of the hardware configuration of the storage battery diagnosis device 1. In FIG. 2, the storage battery diagnosis device 1 includes a controller 20. The controller 20 includes a processor 20a and a storage device 20b. Functions of the respective units composing the storage battery diagnosis device 1, i.e., functions of the data point sequence generation unit 5, the feature point set extraction unit 6, the reference data provision unit 7, and the point set registration unit 8, are realized by software, firmware, or a combination thereof.

The software and the firmware are described as programs and are stored in the storage device 20b. The processor 20a reads any of the programs stored in the storage device 20b and executes the program, thereby realizing the function of the corresponding unit of the storage battery diagnosis device 1.

With reference back to FIG. 1, description will be continued. The current detection device 3 detects a current of the storage battery 2 and outputs the detected current I to the data point sequence generation unit 5. The voltage detection device 4 detects a voltage of the storage battery 2 and outputs the detected voltage V to the data point sequence generation unit 5.

In the following description, the sampling period of time-series data is defined as ts seconds. However, the sampling period does not need to be fixed at ts seconds and may be variable.

In the present description, the storage battery 2 to be subjected to a diagnosis is assumed to be a single storage battery cell, and the single storage battery cell is assumed to be a single-cell lithium-ion battery, unless otherwise specified. Meanwhile, if the storage battery 2 is composed of a plurality of storage batteries, the current detection device 3 and the voltage detection device 4 may detect a current and a voltage of each of the unit storage batteries. In this case, each of the following units performs the same operation a certain number of times, the number being equal to the number of the target storage batteries 2. Here, each unit storage battery may be a storage battery cell or a storage battery module having a combination of storage battery cells connected in series or connected in parallel.

The data point sequence generation unit 5 calculates time-series data {qₖ, k=0, 1, . . . , and N} of a capacity qₖ on the basis of the sampling period tₛ and time-series data {Iₖ, k=0, 1, . . . , and N} of the inputted current value I.

Specifically, calculation can be performed with, for example, the following updating expression.

$$\begin{matrix}[ Mathematical 1 ] & \\ {q}_{k + 1} = {q}_{k} + {t}_{s} {I}_{k} & ( 1 )\end{matrix}$$

The initial capacity q₀ may be 0. Alternatively, in a case where an SOC estimated value can be acquired, calculation may be performed as follows on the basis of, for example, an initial SOC estimated value s₀ and a predetermined full charge capacity qₘₐₓ.

$$\begin{matrix}[ Mathematical 2 ] & \\ {q}_{0} = {q}_{max} \cdot {s}_{0} & ( 2 )\end{matrix}$$

Alternatively, it is also possible to use the relationship between an open circuit voltage (OCV) and the SOC of the storage battery 2, the relationship being expressed as follows.

$$\begin{matrix}[ Mathematical 3 ] & \\ SOC = f ( OCV ) & ( 3 )\end{matrix}$$

That is, in a case where this relationship is known, calculation may be performed as follows on the basis of an initial voltage V₀ and the predetermined full charge capacity qₘₐₓ by using the relationship.

$$\begin{matrix}[ Mathematical 4 ] & \\ {q}_{0} = {q}_{max} f ( {V}_{0} ) & ( 4 )\end{matrix}$$

In addition, the data point sequence generation unit 5 calculates time-series data {V⁽¹⁾, k=0, 1, . . . , and N} of a derivative voltage on the basis of time-series data {Vₖ, k=0, 1, . . . , and N} of the inputted voltage value V and the calculated time-series data {qₖ, k=0, 1, . . . , and N} of the capacity. Here, V^{(j)}ₖ is defined as follows.

$$\begin{matrix}[ Mathematical 5 ] & \\ {V}_{k}^{( j )} := \frac{{d}^{j} V}{{dq}^{j}} {\vert}_{q = {q}_{k}} & ( 5 )\end{matrix}$$

For calculation of the derivative voltage, various numerical differentiation methods can be employed. For example, a derivative voltage at a time point k can be calculated as follows.

$$\begin{matrix}[ Mathematical 6 ] & \\ {V}_{k}^{( 1 )} = \frac{{V}_{k + 1} - {V}_{k - 1}}{{q}_{k + 1} - {q}_{k - 1}} & ( 6 )\end{matrix}$$

In data of constant current charging or constant current discharging, the derivative voltage can be calculated also by using a constant Δq:=tₛI according to the following expression.

$$\begin{matrix}[ Mathematical 7 ] & \\ {V}_{k}^{( 1 )} = \frac{{V}_{k + 1} - {V}_{k - 1}}{2 Δ q} & ( 7 )\end{matrix}$$

In this case, the value of the denominator does not fluctuate between time points, and thus the derivative voltage can be more stably calculated.

If the derivative voltage is calculated through such numerical differentiation, a problem arises in that an error included in the acquired current and/or voltage is amplified. As a countermeasure against this problem, noise may be eliminated from the acquired current and/or voltage through smoothing or the like. As means for eliminating noise, a low-pass filter, Fourier analysis, wavelet analysis, or the like can be employed. As the low-pass filter, various filters such as a moving average filter, a Gaussian filter, a Kolmogorov-Zurbenko filter, a Savitzky-Golay filter, and an active filter are known.

The time-series data to be outputted from the data point sequence generation unit 5 may include not only time-series data obtained during one time of charging/discharging but also time-series data obtained during previous charging/discharging.

Although description is given by using the time-series data of the derivative voltage here, time-series data of a derivative capacity q⁽¹⁾ₖ obtained by differentiating the capacity q with the voltage V may be used.

Time-series data of a second-or higher-order derivative instead of the first-order derivative may be calculated.

Time-series data of a fractional derivative including a non-integer-order derivative may be calculated.

Time-series data of a plurality of different types of derivatives (for example, a derivative capacity and a derivative voltage) and/or derivatives of different orders may be calculated.

The feature point set extraction unit 6 extracts

feature point sets from the inputted data point sequence {(qₖ, V^{(j)}ₖ), k=0, 1, . . . , and N}. Each feature point refers to a point that well represents a shape feature of the data point sequence, and is an inflection point, a local extremum point, a zero crossing point, or the like. However, the feature point is not limited thereto. A publicly-known technique can be employed for detecting the above feature point.

For detecting an inflection point on the data point sequence, a zero crossing point on a second-order derivative of the data point sequence is detected, for example. Alternatively, for directly detecting an inflection point from the original data point sequence, a method described in the following Non-Patent Document 1 or the like can be employed, for example. Typically, detection of an inflection point is performed with distinguishment being made between a concave inflection point at which the state of the data point sequence is switched from a convex (downwardly-convex) state to a concave (upwardly-convex) state, and a convex inflection point at which the state of the data point sequence is switched from the concave (upwardly-convex) state to the convex (downwardly-convex) state.

Non-Patent Document 1: A. Pikaz and I. Dinstein, “Using simple decomposition for smoothing and feature point detection of noisy digital curves”, in IEEE Transactions on Pattern Analysis and Machine Intelligence, vol. 16, no. 8, pp. 808-813, August 1994

For detecting a local extremum point on the data point sequence, a zero crossing point on a first-order derivative of the data point sequence is detected, for example. Alternatively, for directly detecting a local extremum from the original data point sequence, techniques using various algorithms known as so-called peak detection techniques can be employed. Detection of a local extremum point is performed with distinguishment being made between a local maximum point and a local minimum point.

Detection of a zero crossing point on the data point sequence is performed by finding two points at which switching between positive and negative data points occurs, for example. Detection of a zero crossing point is performed with distinguishment being made between a positive zero crossing point at which switching from a negative data point to a positive data point occurs, and a negative zero crossing point at which switching from a positive data point to a negative data point occurs.

In general, if an inflection point on a certain curve is differentiated, a local extremum point is obtained, and, if the local extremum point is differentiated, an inflection point is obtained. Thus, such a characteristic can be utilized for detecting feature points. Alternatively, feature point sets may be detected from a plurality of data point sequences of different orders.

The reference data provision unit 7 provides reference feature point set data to be compared with the feature point set extracted by the feature point set extraction unit 6. In addition, the reference data provision unit 7 may further provide reference storage battery data that serves as a reference when the diagnosis unit 9 performs a diagnosis on the storage battery 2.

The reference feature point set is, for example, a feature point set acquired from a data point sequence of a new storage battery of the same type as the storage battery 2, the data point sequence having a horizontal axis indicating capacity and a vertical axis indicating charging/discharging voltage.

The reference storage battery data is, for example: a data point sequence having a horizontal axis indicating capacity and a vertical axis indicating charging/discharging voltage, the data point sequence being obtained at the time of a single electrode test of an electrode of the same type as that of the storage battery 2; and/or a data point sequence of a new storage battery of the same type as the storage battery 2, the data point sequence having a horizontal axis indicating capacity and a vertical axis indicating charging/discharging voltage and/or charging/discharging OCV.

The reference data (the reference feature point set data and/or the reference storage battery data) to be provided by the reference data provision unit 7 may be acquired from outside, another portion inside the storage battery-equipped system equipped with the storage battery diagnosis device 1, a data center, the cloud, and/or the like. Alternatively, the reference data may be saved inside the reference data provision unit 7. The acquisition source for the reference data to be provided by the reference data provision unit 7 is not limited to a specific acquisition source.

The point set registration unit 8 performs point set registration between the feature point set of the storage battery 2 and the reference feature point set on the basis of the extracted feature point set of the storage battery 2 and the acquired reference feature point set.

Performing point set registration corresponds to, while appropriately matching points with each other between two point sets, transforming one of the point sets by using a certain transformation parameter, to obtain a transformation parameter that minimizes an evaluation function based on an error between corresponding points.

The transformation mentioned here refers to a transformation performed on one of the point sets, such as linear transformation, affine transformation, nonlinear transformation, rigid transformation, or nonrigid transformation, for example. The linear transformation includes rotation transformation, enlargement/reduction transformation, reflection transformation, and shear transformation. The affine transformation includes translation transformation in addition to the linear transformation. The nonlinear transformation includes, in addition to the affine transformation, any transformation that enables a local change in shape, or the like. The rigid transformation sometimes refers to a transformation including rotation/translation, and a transformation including reflection and/or enlargement/reduction. The nonrigid transformation includes the affine transformation, and, in the context of point set registration, refers to the nonlinear transformation in many cases.

The error mentioned here is defined as the Euclidean distance between the corresponding points, but no limitation to this definition is made. For example, the distance between the points may be defined as a p-norm where p represents any real number not smaller than 0, or a distance defined on one's own may be used. The evaluation function mentioned here is defined as the sum of the squares of the Euclidean distances between points, but no limitation to this definition is made. For example, the evaluation function may be defined as the sum of p-norms where p represents any real number not smaller than 0, may be defined as an evaluation function obtained by adding a penalty term, or may be defined as any of various evaluation functions based on the defined error.

In performing point set registration, various methods can be employed. For example, iterative closest point (ICP) described in Non-Patent Document 2 presented below can be employed. The ICP is a method in which a search step for matching points with each other and a step of estimating a transformation parameter for the registration are alternately repeated so that point set registration is performed. In addition to this, it is also possible to take an approach in which the problem of point set registration is regarded as the problem of minimizing an error function indicating a state of the registration, and a nonlinear optimization method is applied, as described in Non-Patent Document 2.

Non-Patent Document 2: Takeshi Masuda “ICP algorithm (pattern recognition and media understanding)”, IEICE technical report 109. 182 (2009): 151-158.

In addition, as still another method, coherent point drift (CPD) described in the following Non-Patent Document 3 can also be employed. In the CPD, points in one of point sets are regarded as a center point set of a Gaussian mixture model, and, while the topological structure of the point set is maintained, matching and registration with another one of the point sets are performed so as to maximize the posterior probability of the Gaussian mixture model by an EM algorithm.

Non-Patent Document 3: Andriy Myronenko and Xubo Song. “Point set registration: Coherent point drift”, IEEE transactions on pattern analysis and machine intelligence 32. 12 (2010): 2262-2275.

In addition to this method, various methods such as robust point matching (RPM), kernel correlation (KC), and SuperGlue are known. Also, each of these methods has many variations.

In the registration between data point sequences of the storage battery 2, the enlargement/reduction transformation or the translation transformation is performed. For example, in the enlargement/reduction transformation, reduction of a storage battery voltage and/or electrode potential curve due to degradation is reflected. Meanwhile, in the translation transformation, an estimation error of a capacity (or SOC) and/or a deviation in capacity balance between a positive electrode potential and a negative electrode potential is reflected.

The diagnosis unit 9 performs a diagnosis on the storage battery 2 on the basis of the result of the point set registration performed by the point set registration unit 8. At this time, the output from the data point sequence generation unit 5 may be used. Also, the feature point set extraction unit 6 may be used. Also, the diagnosis of the storage battery 2 may be performed by using, as a reference, the reference data acquired from the reference data provision unit 7. For example, the extent of degradation of the storage battery 2, or the positive electrode or the negative electrode of the storage battery 2, is calculated on the basis of an enlargement/reduction parameter obtained as a result of the point set registration, and the capacity and/or the SOC of the storage battery 2, or the positive electrode or the negative electrode of the storage battery 2, is estimated on the basis of a translation parameter.

### Description of Degradation of Storage Battery and Model in which Degradation is Reflected

Hereinafter, degradation of a storage battery and a model in which the degradation is reflected, and an example of diagnosis performed by the above storage battery diagnosis device 1, will be described by using mathematical expressions and the drawings. Firstly, degradation of the storage battery and a model in which the degradation is reflected will be described by using mathematical expressions and the drawings.

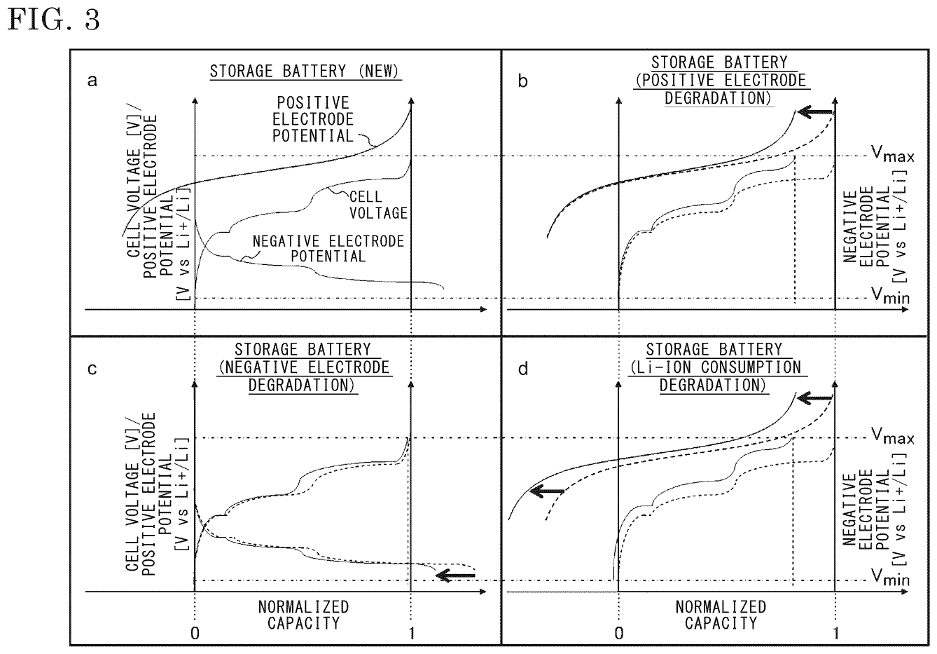

FIG. 3 explains how degradation modes of the storage battery are classified, with the vertical axis indicating voltage or potential and with the horizontal axis indicating normalized capacity. The drawing shows fluctuations, of cell voltage curves and electrode potential curves, that occurred when a new cell in FIG. 3 (a) (on the upper left side of the drawing) experienced positive electrode degradation as in FIG. 3 (b) (on the upper right side of the drawing), negative electrode degradation as in FIG. 3 (c) (on the lower left side of the drawing), and lithium-ion consumption degradation as in FIG. 3 (d) (on the lower right side of the drawing). Here, each broken line indicates a voltage curve or a potential curve obtained regarding the new cell.

The full charge capacity of the cell is defined with an upper limit voltage Vmax and a lower limit voltage Vmin. The voltage of the cell is expressed as the difference between the positive electrode potential and the negative electrode potential. Thus, if the positive electrode potential curve or the negative electrode potential curve is reduced owing to degradation, influence of the reduction is inflicted also on the cell voltage curve.

Also, if the capacity balance differs between the positive electrode and the negative electrode owing to consumption of Li-ions due to a side reaction, when one of the electrode potential curves is regarded as a reference, the other electrode potential curve laterally shifts and the cell voltage curve is also influenced by the shift, as in the lower right side of the drawing. Consequently, the full charge capacity decreases. Such a shift of the electrode potential curve is considered to be mainly attributed to growth of a solid electrolyte interface (SEI) at the time of charging of the negative electrode (i.e., at the time of charging of the cell) or consumption of Li-ions in the course of precipitation of lithium. Therefore, when the negative electrode potential curve is regarded as a reference, the positive electrode potential curve is shifted to the left in many cases.

Considering the above description, a reference cell voltage model is expressed as follows.

$$\begin{matrix}[ Mathematical 8 ] & \\ V ( q ) = {U}_{p} ( q ) - {U}_{n} ( q ) + RI & ( 8 )\end{matrix}$$

Here, q is the capacity of the storage battery, Uₚ is the positive electrode potential, Uₙ is the negative electrode potential, and R is the internal resistance of the storage battery. As the capacity q, a capacity (normalized capacity) normalized according to the manner of handling the data may be used. Further, when the above expression is regarded as a reference, a degraded cell voltage model is expressed as follows by using a degradation parameter group Θ:=[θₚ, δₚ, θₙ, δₙ, θᵣ]^{T}.

$$\begin{matrix}[ Mathematical 9 ] & \\ V ( q ; Θ ) = {U}_{p} ( {θ}_{p}^{- 1} q + {δ}_{p} ) - {U}_{n} ( {θ}_{n}^{- 1} q - {δ}_{n} ) + {θ}_{r} RI & ( 9 )\end{matrix}$$

Here, θₚ is a parameter regarding a positive electrode capacity retention rate, δₚ is a parameter regarding a capacity balance deviation on the positive electrode side, θₙ is a parameter regarding a negative electrode capacity retention rate, δₙ is a parameter regarding a capacity balance deviation on the negative electrode side, and θᵣ is a parameter regarding a resistance increase rate.

Alternatively, in a case where electrode potential information is retained, the degraded cell voltage model can also be expressed as follows with respect to the storage battery capacity q.

$$\begin{matrix}[ Mathematical 10 ] & \\ V ( q ) = {U}_{p} ( \frac{q + {q}_{p , 0}}{{q}_{p , max}} ) - {U}_{n} ( \frac{q + {q}_{n , 0}}{{q}_{n , max}} ) + RI & ( 10 )\end{matrix}$$

Here, when the subscript p or the subscript n is replaced with a subscript e, q_{e,0} is the initial capacity of the corresponding electrode (an electrode capacity at which the storage battery capacity q is 0), and d_{e,max} is the full charge capacity of the electrode.

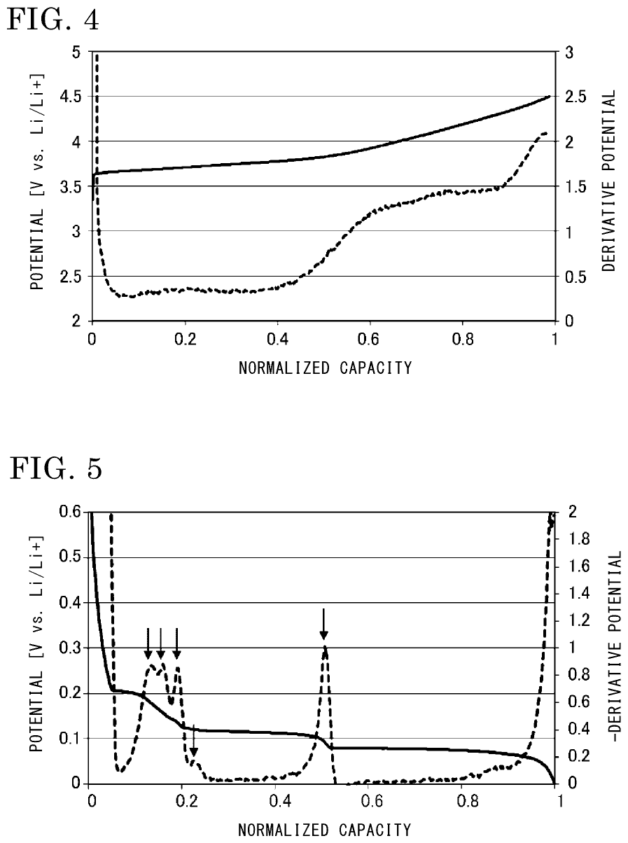

FIG. 4 is a characteristic graph showing a potential curve and a derivative potential curve of a nickel-manganese-cobalt (NMC)-based positive electrode of a lithium-ion battery including the positive electrode and a graphite negative electrode. In FIG. 4, the horizontal axis indicates the normalized capacity of the positive electrode, the left vertical axis indicates the potential of the positive electrode, and the right vertical axis indicates a derivative potential. The solid line indicates a potential curve, and the broken line indicates a derivative potential curve. As is found from FIG. 4, positive electrode potential curves of many materials such as NMC each have a shape in which the potential changes gently.

FIG. 5 is a characteristic graph showing a potential curve and a derivative potential curve of the graphite negative electrode of such a general lithium-ion battery including the NMC-based positive electrode and the negative electrode. In FIG. 5, the horizontal axis indicates the normalized capacity of the negative electrode, the left vertical axis indicates the potential of the negative electrode, and the right vertical axis indicates a derivative potential having an inverted sign. The solid line indicates a potential curve, and the broken line indicates a derivative potential curve. As is found from FIG. 5, the potential curve of the graphite has flat regions and a region in which the potential curve steeply fluctuates, and, with focus being placed on the derivative potential curve, there are a plurality of steep peak shapes as indicated by arrows.

Thus, the shape feature of the potential curve of an electrode differs depending on the material of the electrode. A stepwise (sigmoidal) potential change in such a potential curve, in other words, a peak shape in a derivative potential, is considered to be derived from a phase change phenomenon in electrode particles. Regarding the positive electrode as well, the potential thereof fluctuates although the fluctuation is gentle. This is also considered to be derived from a phase change phenomenon.

### Example of Diagnosis by Storage Battery Diagnosis Device

Next, an example of a diagnosis by the above storage battery diagnosis device 1 will be described by using mathematical expressions and the drawings.

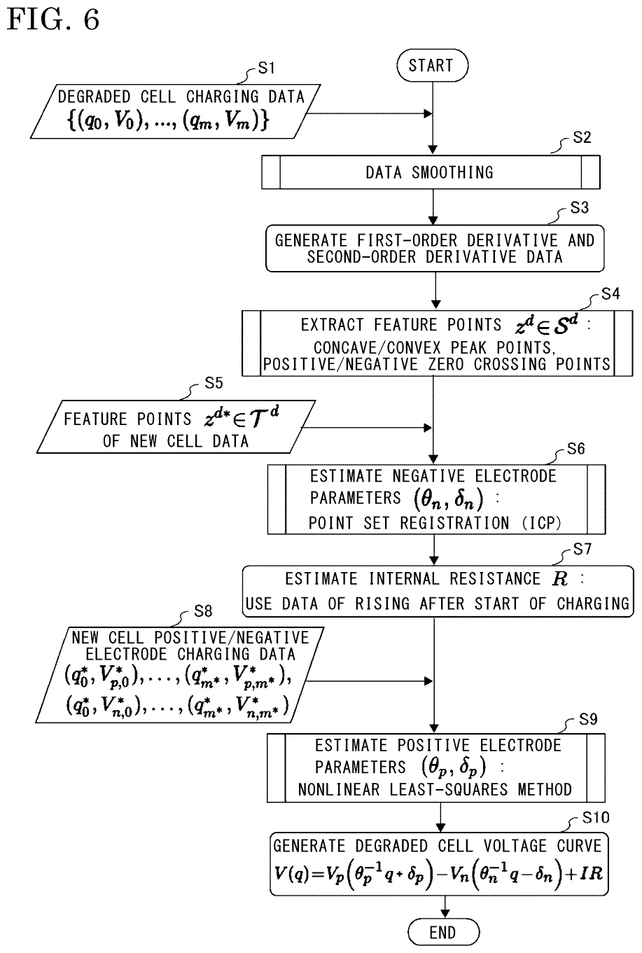

FIG. 6 is an example of a flowchart of a diagnosis in the case of employing ICP in the storage battery diagnosis device 1. For distinguishment between a new cell and a degraded cell, each point regarding data of the new cell is denoted by an asterisk (*) at the upper right side.

First, current data and voltage data of a certain degraded cell at the time of, for example, constant current charging are acquired. Here, data obtained at the time of performing constant current charging to an upper limit voltage of 4.2 V from a state of being SOC=0% has been used on the assumption of a cell obtained by using ternary NMC for a positive electrode and using graphite for a negative electrode.

Next, time-series data {(q₀, V₀), . . . , (qₘ, Vₘ)} of a capacity and a voltage is generated from the data (step S1).

Next, by using the time-series data of the capacity and the voltage as an input, data smoothing is performed (step S2), and time-series data of a first-order derivative and time-series data of a second-order derivative are created (step S3).

Next, feature points zdesd are extracted (step S4). Here, d is a numbering for each type of feature point, and, in this example, d takes values of 1, 2, 3, and 4 which respectively correspond to a local maximum point, a local minimum point, a positive zero crossing point, and a negative zero crossing point. S^{d} represents an ordered set of the types d of the feature points, and z^{d} is a vector obtained by vertically arraying the feature points belonging to S^{d}. As described later, one-dimensional ICP is assumed in this example, and thus elements of z^{d} and S^{d} are values corresponding to the horizontal-axis positions of the respective types d of feature points.

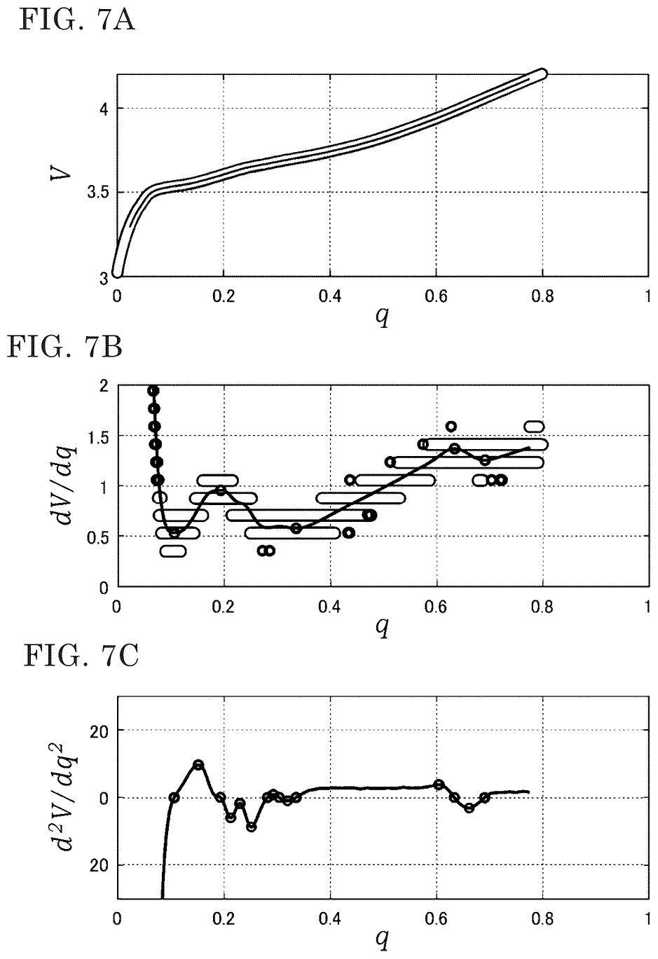

FIG. 7 shows a plotted voltage (in FIG. 7 (a)), a plotted first-order derivative voltage (in FIG. 7 (b)), and a plotted second-order derivative voltage (in FIG. 7 (c)) of the degraded cell. Here, q in the horizontal axis represents a normalized capacity with the full charge capacity in the case of a new cell being defined as 1. In FIG. 7 (a) and FIG. 7 (b), raw data and post-smoothing data are plotted, and, in FIG. 7 (c), only post-smoothing data is plotted. Raw data of the second-order derivative in FIG. 7 (c) is not shown since the raw data have values that are, owing to influence of a measurement error and a quantization error, discrete to the extent that the outline of the raw data cannot be ascertained. In addition, four types of feature points, i.e., local maximum points, local minimum points, positive zero crossing points, and negative zero crossing points, are plotted on the post-smoothing curves in FIG. 7 (a) and FIG. 7 (b).

From FIG. 7, it is found that smoothing resulted in enablement of decrease of errors of measurement data while maintaining the shape features of the original curves. In addition, it is found that extraction of the feature points led to enablement of feature extraction so as to ascertain the shape features of the first-order derivative curve and the second-order derivative curve. In particular, in the second-order derivative curve in FIG. 7 (c), in addition to negative zero crossing points corresponding to respective local maximum points on the first-order derivative curve in FIG. 7 (b) and positive zero crossing points corresponding to respective local minimum points on the first-order derivative curve in FIG. 7 (b), local maximum points corresponding to respective concave inflection points on the first-order derivative curve and local minimum points corresponding to respective convex inflection points on the first-order derivative curve have also been detected. Thus, even in extraction of the same types of feature points, more features have been extracted on the second-order derivative curve in FIG. 7 (c).

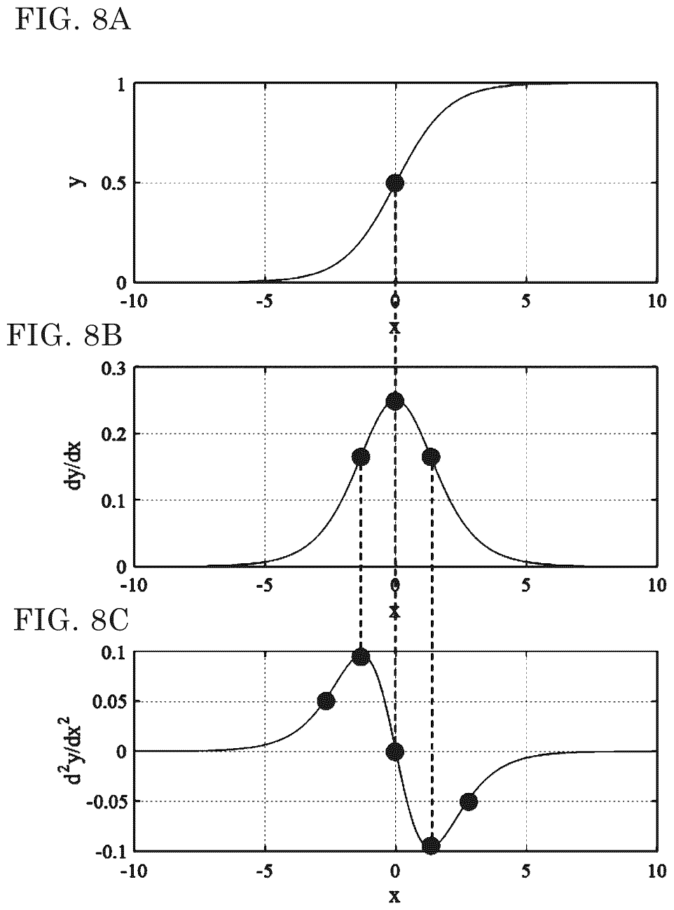

FIG. 8 shows an example of a sigmoid curve y (in FIG. 8 (a)), and a first-order derivative curve dy/dx (FIG. 8 (b)) and a second-order derivative curve d2y/dx2 (FIG. 8 (c)) of the sigmoid curve y. The inflection point on the sigmoid curve in FIG. 8 (a) corresponds to the local maximum point on the first-order derivative curve in FIG. 8 (b) and the negative zero crossing point on the second-order derivative curve in FIG. 8 (c). The concave inflection point and the convex inflection point on the first-order derivative curve in FIG. 8 (b) respectively correspond to the local maximum point and the local minimum point on the second-order derivative curve in FIG. 8 (c). It is known that, as described above, differentiation of a concave inflection point leads to obtainment of a local maximum point and differentiation of the local maximum point leads to obtainment of a negative zero crossing point, and meanwhile, differentiation of a convex inflection point leads to obtainment of a local minimum point and differentiation of the local minimum point leads to obtainment of a positive zero crossing point. Therefore, if existence of corresponding feature points is ascertained between voltage curves and/or derivative curves of different orders, it is also possible to increase the robustness of feature point extraction.

With reference to FIG. 7, it can be confirmed with certainty that the local extremum points on the first-order derivative curve in FIG. 7 (b) and the zero crossing points on the second-order derivative curve in FIG. 7 (c) coincide with each other in the horizontal axis. Also, as already described, each electrode potential curve of a storage battery undergoes a stepwise potential change owing to a phase change, and thus expression can be performed with a function including the sum of a sigmoid function. Therefore, the robustness can also be increased by: interpreting FIG. 8 as showing the relationship between the derivatives and the feature points regarding the sigmoid curve; and checking, according to the derivative order, whether the sequence of the types of feature points extracted from target data is a sequence that is consistent in a case where interpretation as the sum of the sigmoid function is performed.

Next, feature points z^{*d}∈T^{d} of new cell data serving as a reference are extracted (step S5 in FIG. 6). As the new cell data as well, constant current charging data until arrival at the upper limit voltage of 4.2 V from a state of being SOC=0%, has been used in the same manner as in the degraded cell data. Here, d is a numbering for each type of feature point, and, in the same manner as that for the degraded cell, d takes values of 1, 2, 3, and 4 which respectively correspond to a local maximum point, a local minimum point, a positive zero crossing point, and a negative zero crossing point. T^{d} represents a set of the types d of the feature points in the new cell data, and z^{*d} represents a vector obtained by vertically arraying feature points belonging to the types d of the feature points in the new cell data.

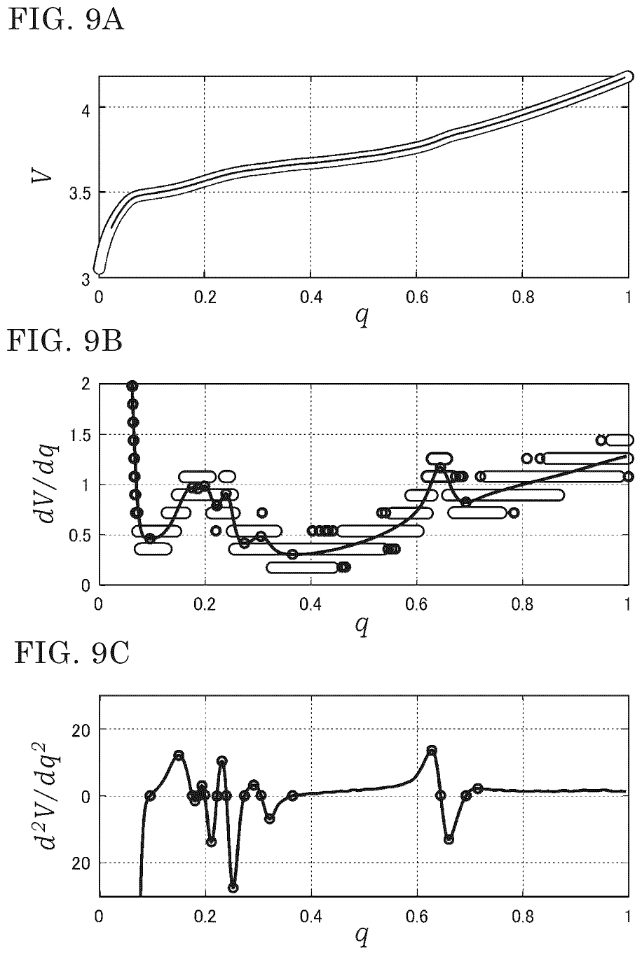

FIG. 9 shows a plotted voltage (in FIG. 9 (a)), a plotted first-order derivative voltage (in FIG. 9 (b)), and a plotted second-order derivative voltage (in FIG. 9 (c)) of the new cell. Description of the drawing is the same as that of FIG. 7, and thus is omitted. In comparison with the degraded cell in FIG. 7, the shape features of a post-smoothing first-order derivative curve (in FIG. 9 (b)) and a post-smoothing second-order derivative curve (in FIG. 9 (c)) are more distinct, and more feature points are extracted. From another perspective, in the data of the degraded cell, some of the feature points on the curves have vanished owing to degradation. This is considered to be because degradation of an electrode led to increase in the distribution of the concentration of lithium-ions inside the electrode, as described with respect to the problem. Meanwhile, despite the fact that such smoothing or local vanishment of the shape features is observed, comparison in terms of the shape of and the feature points on the second-order derivative curve between the new cell in FIG. 9 (c) and the degraded cell in FIG. 7 (c) leads to the finding that the correspondence relationship of the shape features still remains.

The feature points on the first-order derivative curve and the second-order derivative curve extracted as above are considered to be derived from graphite. This is known through comparison between: FIG. 7 and FIG. 9; and the shapes of the derivative potential curve of ternary NMC in FIG. 4 and the derivative potential curve of graphite in FIG. 5.

Firstly, with reference to the first-order derivative potential curves in FIG. 7 (b) and FIG. 9 (b), these curves are found to have resulted from synthesis of a gentle positive-electrode derivative potential curve such as one in FIG. 4 and a steep negative-electrode derivative potential curve such as one in FIG. 5. Further, with reference to the second-order derivative potential curves in FIG. 7 (c) and FIG. 9 (c), it can be considered that low-frequency components, of the first-order derivative potential curves in FIG. 7 (b) and FIG. 9 (b), derived from the positive electrodes were decreased through differentiation, and in contrast, high-frequency components, of said first-order derivative potential curves, derived from the negative electrodes were emphasized through differentiation, whereby curves with feature shapes derived from the negative electrodes being dominant were extracted. Furthermore, regarding the feature points as well, it can be determined from FIG. 5, FIG. 7, and FIG. 9 that vertical/horizontal deviations partially occurred owing to influence of the positive electrode curves, but all the feature points are derived from the negative electrodes.

If all or many of the feature points in each of the second-order derivative curves in FIG. 7 (c) and FIG. 9 (c) are derived from one of the electrodes, it is considered that registration of the feature point sets between the new cell and the degraded cell leads to inference of a degradation parameter of the electrode. That is, if point set registration of the feature point set on the second-order derivative curve of the degraded cell in FIG. 7 (c) is performed with use of an enlargement/reduction parameter and a translation parameter, an electrode capacity retention rate can be estimated from the enlargement/reduction parameter, and an electrode capacity deviation or an SOC estimation error can be estimated from the translation parameter.

Here, a case of performing point set registration through ICP is contemplated as an example. Further, as an example, one-dimensional ICP in which error in only a horizontal axis is considered is contemplated. Consequently, estimation of a transformation parameter is reduced to the linear least-squares method, and the speed and the stability of numerical calculation are increased. Further, the characteristic that the second-order derivative voltage curve of the storage battery becomes gentler owing to degradation leads to significant fluctuation of the value (in the vertical axis) of each feature point, and meanwhile, does not lead to much fluctuation of the position (in the horizontal axis) of the feature point. Thus, the one-dimensional ICP can be said to be a method suitable for the characteristic regarding degradation of the storage battery.

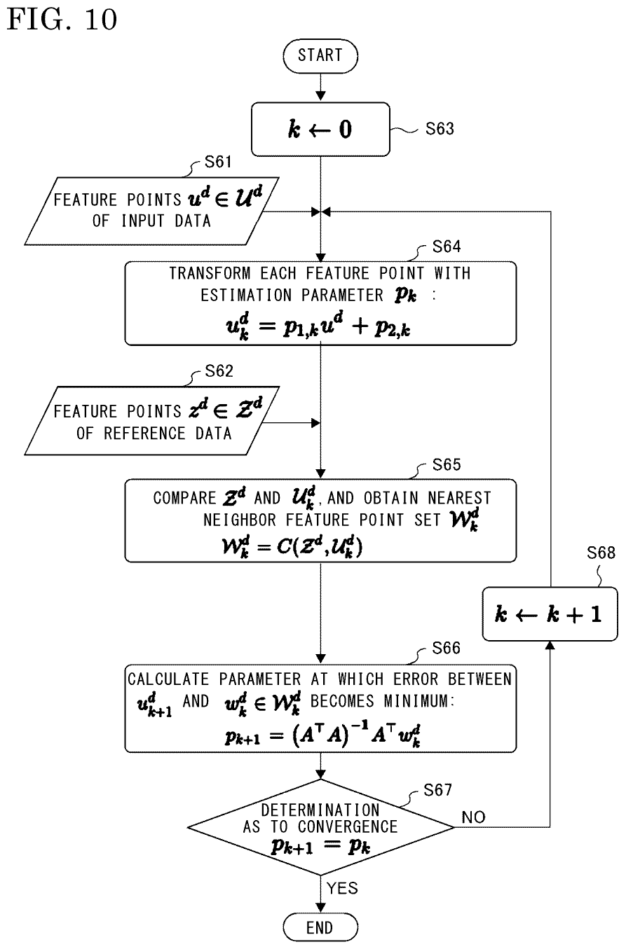

FIG. 10 is a flowchart of the one-dimensional ICP. It is assumed that u^{d}∈U^{d} is given as feature points of input data (step S61 in FIG. 10), and z^{d}∈Z^{d} is given as feature points of reference data (step S62). In the examples described above, the feature points of the degraded cell correspond to the feature points of the input data, and the feature points of the new cell correspond to the feature points of the reference data.

First, at k=0 (step S63), an initial value p₀ is applied to an estimation parameter pₖ:=[p_{1,k}, . . . p_{2,k}]^{T} with a first element thereof being an enlargement/reduction parameter and with a second element thereof being a translation parameter.

Next, each of the feature points udeud of the input data is transformed as follows by using the estimation parameter pₖ (step S64).

$$\begin{matrix}[ Mathematical 11 ] & \\ {u}_{k}^{d} = {p}_{1 , k} {u}^{d} + {p}_{2 , k} & ( 11 )\end{matrix}$$

Then, the set Z^{d} and the set U^{d}ₖ are compared with each other, and a nearest neighbor feature point set W^{d}ₖ is obtained as follows (step S65).

$$\begin{matrix}[ Mathematical 12 ] & \\ {𝒲}_{k}^{d} = 𝒞 ( {𝒵}^{d} , {𝒰}_{k}^{d} ) & ( 12 )\end{matrix}$$

Here, C (x, y) is, for example, a function for obtaining, on the basis of ordered sets x and y, a partially ordered set of the ordered set x with which the sum of the squares of errors, as Euclidean distances, relative to respective elements of the ordered set y becomes minimum. However, the measure of the errors may be one other than the Euclidean distance, and limitation to the sum of the squares does not necessarily have to be made. Here, the point sets are matched with one another.

As seen in FIG. 7 and FIG. 9, a further degradation leads to a gentler n^{th}-order derivative voltage curve of the storage battery and leads to a smaller number of feature points on the curve. Thus, in the data (the input data mentioned herein) of the degraded cell being subjected to the diagnosis, the total number of the feature points tends to be smaller than that in reference cell data (the reference data mentioned herein). In an operation of obtaining the partially ordered set W^{d} of the reference data Z^{d} with the above expression, such a characteristic of the storage battery is naturally reflected. The nearest neighbor point set may be acquired through full search or may be acquired by using an existing algorithm.

Next, calculation of an estimation parameter pₖ₊₁ with the iteration number being k+1 is contemplated. First, the relationship between the parameter p and the already obtained W^{d}ₖ is expressed as follows.

$$\begin{matrix}[ Mathematical 13 ] & \\ {w}_{k}^{d} = {p}_{1} {u}^{d} + {p}_{2} + {ε}^{d} & ( 13 )\end{matrix}$$

Here, ε^{d} is a vector indicating an error. In this case, the relationship in the above expression at d=1, 2, 3, 4 is summarized as follows.

$$\begin{matrix}[ Mathematical 14 ] & \\ {w}_{k} = Ap + ε & ( 14 )\end{matrix}$$

Here, the following relationship is established.

$$\begin{matrix}[ Mathematical 15 ] & \\ \begin{matrix}{w}_{k} := {[ {w}_{k}^{1 ⊤} , {w}_{k}^{2 ⊤} , {w}_{k}^{3 ⊤} , {w}_{k}^{4 ⊤} ]}^{⊤} , & ε\end{matrix} := {[ {ε}^{1 ⊤} , {ε}^{2 ⊤} , {ε}^{3 ⊤} , {ε}^{4 ⊤} ]}^{⊤} & \end{matrix}$$

Here, A represents a coefficient matrix defined as follows.

$$\begin{matrix}[ Mathematical 16 ] & \\ A := [ \begin{matrix}{u}^{1} & {1}^{1} \\ {u}^{2} & {1}^{2} \\ {u}^{3} & {1}^{3} \\ {u}^{4} & {1}^{4}\end{matrix} ] & ( 15 )\end{matrix}$$

Here, l^{d} represents a vector that has the same dimension as that of a d^{th} feature quantity and in which all the elements are l. Thus, since expression (8) is a linear least-squares problem, a solution at which the sum of the square errors becomes minimum can be obtained, and the estimated value p^{k+1} is calculated as follows (step S66).

$$\begin{matrix}[ Mathematical 17 ] & \\ {p}_{k + 1} = {( {A}^{⊤} A )}^{- 1} {A}^{⊤} {w}_{k} & ( 16 )\end{matrix}$$

According to a certain normal distribution having an average of 0 with elements of a being independent of one another, the derived solution is known to be equal to a maximum likelihood estimated value. Since the linear least-squares method is employed in the proposed technique, the proposed technique is advantageous in that: repetitive calculation is unnecessary in estimation of a parameter in each step; and an optimal solution can be uniquely obtained without dependence on an initial value.

Lastly, the estimation parameters pₖ₊₁ and pₖ are compared with each other to check whether these parameters take the same value, whereby determination as to convergence is performed (step S67). If these parameters take the same value as a result of the comparison, the process is ended. Meanwhile, if these parameters are different from each other as a result of the comparison, calculations performed up until this step are repeated with k+1 being applied as k (step S68), until these parameters take the same value. The nearest neighbor feature point set and the linear least-squares solution calculated in the course of the process are each for minimizing the error in the sum of the squares between the point sets. Therefore, in any of the calculation steps, the error in the sum of the squares is of a monotonically non-increasing type, and convergence to a local minimum value through repetitive calculation is guaranteed.

Through the above method, point set registration was performed with the initial parameter being set to p₀=[0.1, 0.2]^{T}. This initial parameter is a parameter arbitrarily set so as to have a large error for convenience of description.

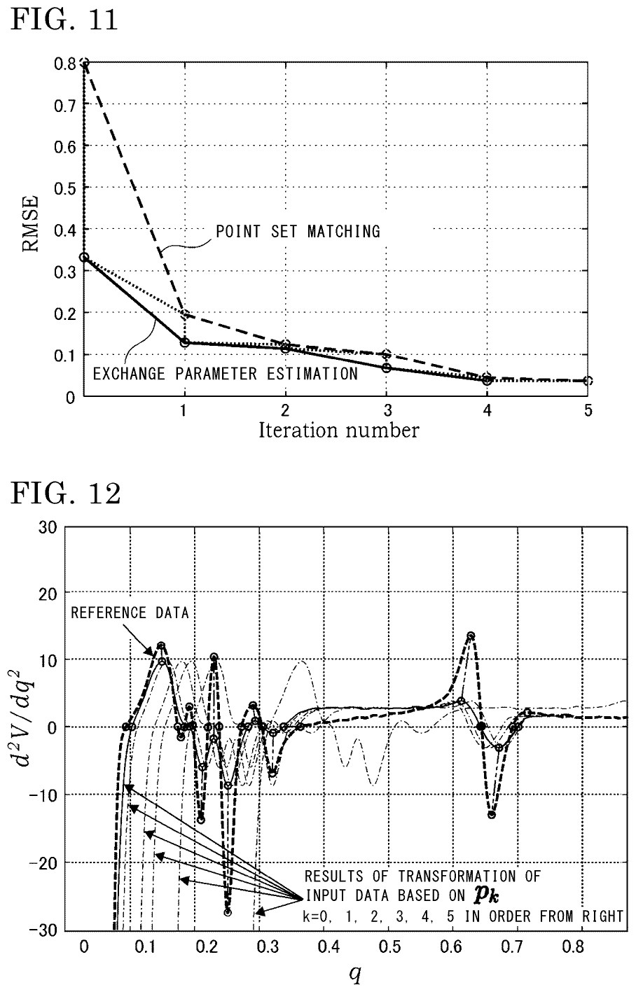

FIG. 11 shows changes in the root mean square errors (RMSEs) of results of point set registration performed through the one-dimensional ICP. The horizontal axis indicates the iteration number, and both the RMSE of the result of the point set matching step and the RMSE of the result of the transformation parameter estimation step are plotted. Here, the RMSE in the transformation parameter estimation is an RMSE at the time of use, as a transformation parameter, of pₖ₊₁ calculated in a k^{th} step. By alternately performing point set matching and transformation parameter estimation, the RMSE decreases in a monotonically non-increasing manner as indicated by a broken line.

FIG. 12 shows reference data and results of transformation of input data based on pₖ at k=0, 1, 2, 3, 4, 5. Here, markers of feature point sets are plotted only on the reference data and the result of transformation of the input data based on ps, and matched feature points are connected to each other by solid lines. Among the results of transformation of the input data, the result at which k is smallest significantly deviates from the reference data. Meanwhile, as k becomes larger, the corresponding result further approaches the reference data, and, when k is largest, i.e., 5, the errors relative to the corresponding feature points in the reference data are very small.

As a result, although there is a significant difference in the gentleness of the curve between the reference data and the input data, the outlines of the curves and the feature points coincide well with each other. The result of the parameter estimation is p₀=[1.0205, −0.0038]^{T}. With this estimation result being regarded as a negative electrode parameter, the negative electrode capacity retention rate is 98.0%, and the error of the normalized capacity is −0.38%. The estimation result indicating that the negative electrode capacity retention rate is nearly 100% is consistent with a visually observed result indicating that the distances between the corresponding feature points on the first-order derivative curves and the second-order derivative curves in FIG. 7 and FIG. 9 remain substantially unchanged. In addition, the data of the new cell and the data of the degraded cell are each obtained by adjusting the normalized capacity in advance, and thus the estimation result indicating that the error of the normalized capacity is nearly 0% is as expected.

The above process is a calculation process performed in the case of, for example, employing the one-dimensional ICP and performing point set registration on the feature point sets of data of the second-order derivative voltages of the reference cell and the degraded cell.

Next, an internal resistance R is estimated (step S7) with reference back to FIG. 6. The operation described from this paragraph is also an example of an internal operation of the diagnosis unit 9. The internal resistance R may be estimated as one of parameters at the time of positive electrode parameter estimation described later. Here, a case where only the internal resistance R is independently acquired is contemplated.

In order to acquire the internal resistance R, the following method is described as an example. That is, the inputted charging/discharging data point sequence includes a current and a voltage at elapse of k₀ seconds during an inoperativeness period immediately before charging/discharging starts, and a current and a voltage at elapse of k_{0+N} seconds after N seconds have passed since charging/discharging started, and the internal resistance during the N seconds is calculated on the basis of the currents and the voltages as follows.

$$\begin{matrix}[ Mathematical 18 ] & \\ {R}_{N} = \frac{{V}_{{k}_{0} + N} - {V}_{{k}_{0}}}{{I}_{{k}_{0} + N} - {I}_{{k}_{0}}} & ( 17 )\end{matrix}$$

Ideally, data of constant current charging or constant current discharging during the N seconds is used. The value of N is desirably set to be about 60 seconds to 300 seconds such that the internal resistance also includes a diffusion resistance having a long time constant of several seconds to several hundreds of seconds. However, if the number of seconds is set to be excessively large, error due to fluctuation of the OCV increases, and thus caution must be taken.

As a more advanced method, the following method may be employed. That is, the internal resistance is divided into elements such as an electrolyte resistance, a charge transfer resistance, and a diffusion resistance of a DC component, an equivalent circuit model or the like is created, and a parameter of each of the elements is estimated. If the storage battery system equipped with the storage battery 2 has separately acquired an internal resistance, the value of this internal resistance may be used.

Next, a method for estimating a positive electrode (degradation) parameter of the degraded cell (step S9) will be described. The positive electrode parameter is estimated as follows. First, an overvoltage component based on the internal resistance and a negative electrode potential curve are subtracted from the storage battery voltage with use of expression (9) regarding the storage battery voltage curve on the basis of the data point sequence of the degraded cell, and the already-obtained negative electrode parameter and the already-obtained internal resistance, whereby a positive electrode potential curve of the degraded cell is calculated (step S10). For calculation of the negative electrode potential curve of the degraded cell used here, information about the negative electrode potential retained in advance is used (step S8). For example, if data or a model of a single electrode potential curve of a storage battery of the same type as the storage battery 2 or a storage battery having a negative electrode that is of the same type as that of the storage battery 2 is retained, a negative electrode potential curve of the degraded cell can be created from the data or the model, and the negative electrode parameter.

Likewise, an overvoltage component based on the internal resistance of the new cell, and a negative electrode potential curve based on the data or the model are subtracted from the data of the new cell voltage, whereby a positive electrode potential curve of the new cell is calculated (step S10).

Positive electrode parameters are estimated so as to lead to a small error between the positive electrode potential curve of the new cell and the positive electrode potential curve of the degraded cell which have been thus calculated. Here, θₚ and δₚ in expression (9) are estimated as the positive electrode parameters. However, in a case where the internal resistance R has been neither acquired nor subtracted in the previous step, estimation is performed with the resistance parameter θᵣ also being included among estimation parameters.

Each negative electrode potential curve significantly fluctuates at around a capacity of 0. Owing to influence of this fluctuation, an error is easily included also in the corresponding positive electrode potential curve to be calculated. Considering this, no positive electrode potential curve at around a capacity of 0 is calculated.

In a case where the positive electrode potential curve of the new cell and/or the degraded cell is a data point sequence, an error is evaluated with a value in the vertical axis being calculated at each fixed interval in the horizontal axis by interpolation between pieces of data, for example. As the interpolation, various methods such as linear interpolation and spline interpolation can be employed.

Meanwhile, in a case where the positive electrode potential curve of the new cell and/or the degraded cell is a functional model, a value in the vertical axis only has to be calculated according to the functional model at each fixed interval in the horizontal axis, for example. An evaluation function based on errors is used for positive electrode parameter estimation, and any of functions defined in various manners can be used as the evaluation function, as already mentioned. Here, the sum of the squares of errors at respective points is used.

As a specific method for positive electrode parameter estimation, various existing methods based on nonlinear optimization theories can be employed. For example, various methods such as the Gauss-Newton method, the Levenberg-Marquardt method, penalty function methods, sequential quadratic programming methods, and generalized reduced gradient (GRG) methods are known, and no limitation to any specific method is made.

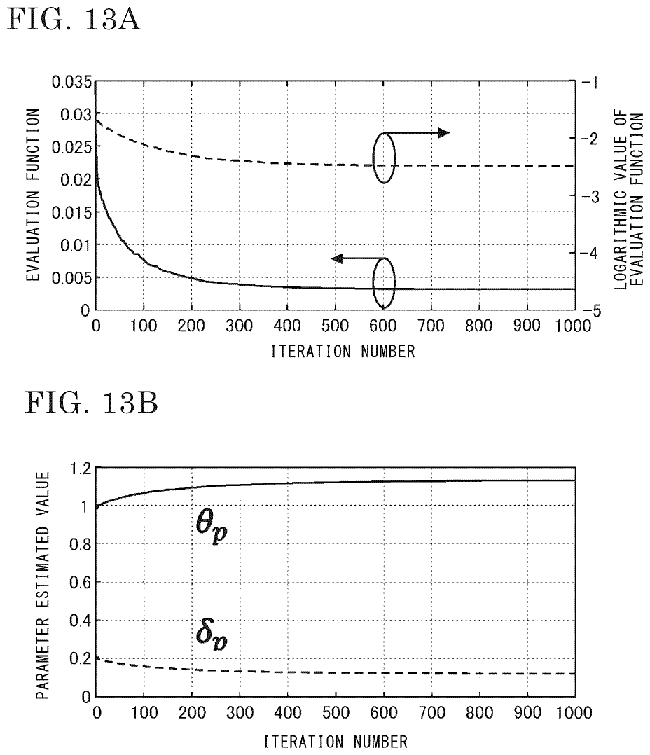

FIG. 13 shows results of estimating positive electrode parameters through repetitive calculation according to a certain nonlinear optimization method. In FIG. 13 (a), the left axis indicates the evaluation function, and the right axis indicates the logarithmic value of the evaluation function to a base of 10. In FIG. 13 (b), the vertical axis indicates the estimated value of each positive electrode parameter. In each of FIG. 13 (a) and FIG. 13 (b), the horizontal axis indicates the iteration number. According to FIG. 13, each parameter estimated value converges to a fixed value in the course of repetitive calculation, and, in association with the convergence, the evaluation function also converges to a fixed value. With reference to the logarithmic value of the evaluation function, the logarithmic value definitely converges to a fixed value as well. Judging from the parameter estimated value, the positive electrode capacity retention rate is 88.6%, and the capacity deviation is 11.9%.

In this manner, estimation of the negative electrode parameter and estimation of the positive electrode parameter are separately performed, whereby the number of parameters to be estimated at one time decreases, the difficulty of estimation decreases, and the calculation speed is also improved.

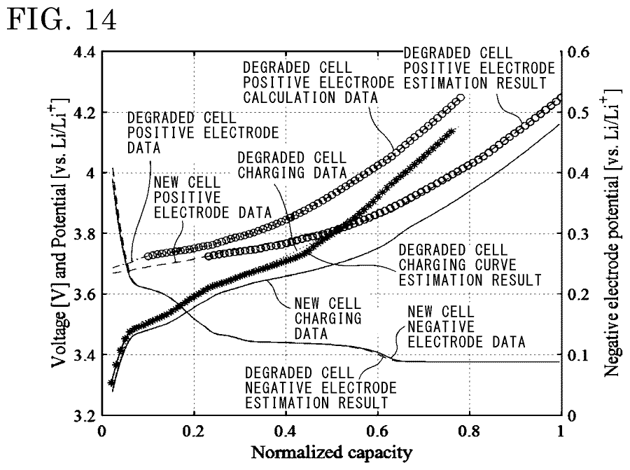

FIG. 14 shows data and estimation results regarding the positive electrode and the negative electrode of each of the new cell and the degraded cell, and regarding the cells. It is found that, ultimately, charging data of the degraded cell and a charging curve created again through estimation of each degradation parameter of the degraded cell substantially coincide with each other.

In the manner described above, the positive electrode parameter, the negative electrode parameter, and the resistance degradation parameter regarding degradation of the storage battery 2 have been estimated, and charging data of the degraded cell has been created again by using these parameters. Although charging data covering a wide range of capacities has been used for description given above, the technique in the present embodiment is also applicable to partial charging data.

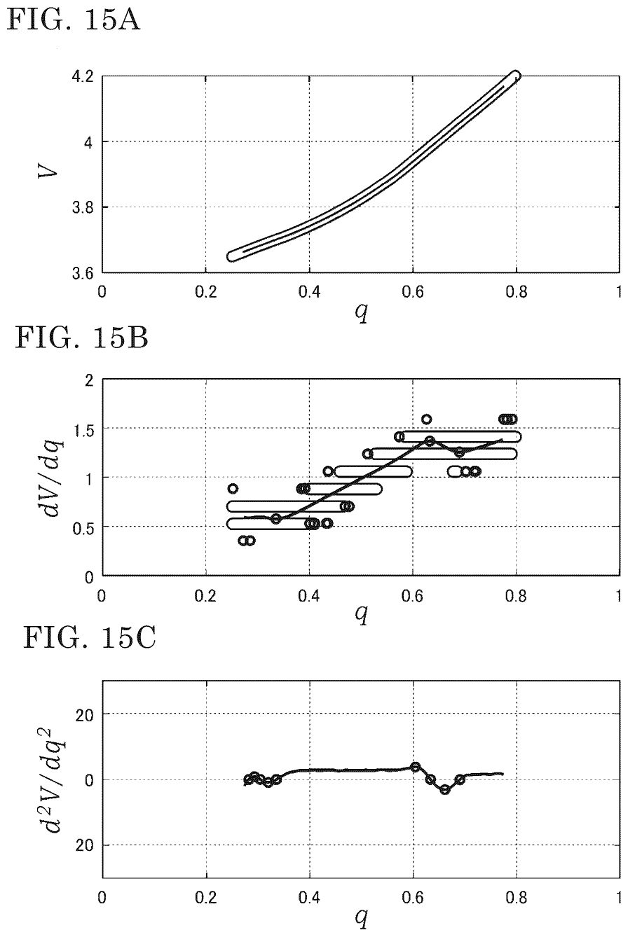

FIG. 15 shows results of performing smoothing processing on partial charging data of the same storage battery and extracting feature points. Description of FIG. 15 is the same as those of FIG. 7 and FIG. 9, and thus is omitted. From a first-order derivative voltage curve in FIG. 15 (b), only three feature points have been acquired. Meanwhile, from a second-order derivative voltage curve in FIG. 15 (c), nine feature points have been acquired, whereby plenty of information has been acquired from few shape features of the original voltage curve.

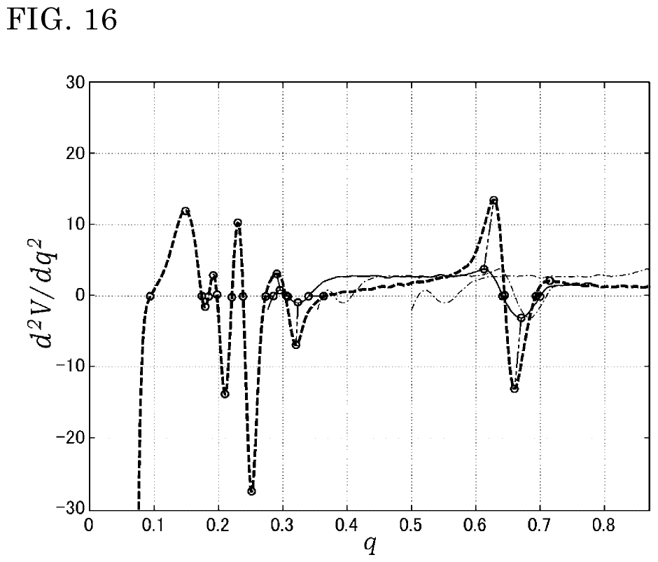

FIG. 16 shows a result of performing point set registration through the one-dimensional ICP between the new cell and the degraded cell. Description of FIG. 16 is the same as that of FIG. 12, and thus is omitted. If comprehensive judgement is performed from plenty of feature points extracted from the second-order derivative voltage curve in FIG. 15 (c), it is found that registration between the feature point sets has been achieved. Regarding estimation results of the negative electrode parameters, the negative electrode capacity retention rate is 98.8%, the SOC error is 0.07%, and these estimation results coincide well with the estimation results regarding the full-charging data described above.

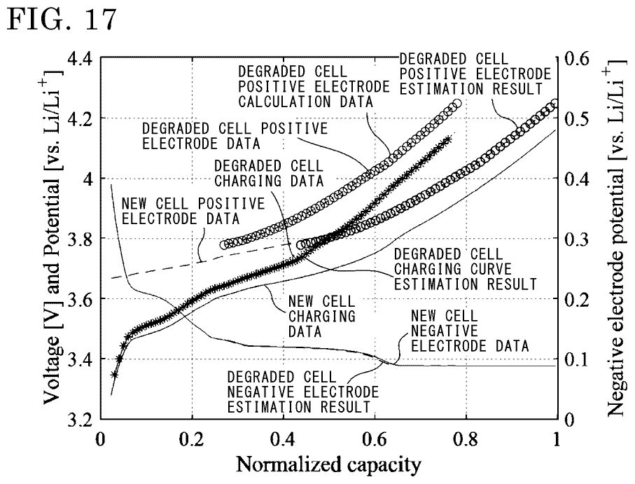

Similar to the case of full-charging in FIG. 14, FIG. 17 shows data and estimation results regarding the positive electrode and the negative electrode of each of the new cell and the degraded cell, and regarding the cells. Regarding estimation results of the positive electrode parameters, the positive electrode capacity retention rate is 91.6%, the capacity deviation is 14.3%, and these estimation results also have values close to those of the estimation results regarding the full-charging data. In addition, a cell OCV curve formed again has a similar shape. The above content is an example in which the storage battery diagnosis device 1 according to the present embodiment has been applied.

### Procedure of Processing Performed through Storage Battery Diagnosis Method

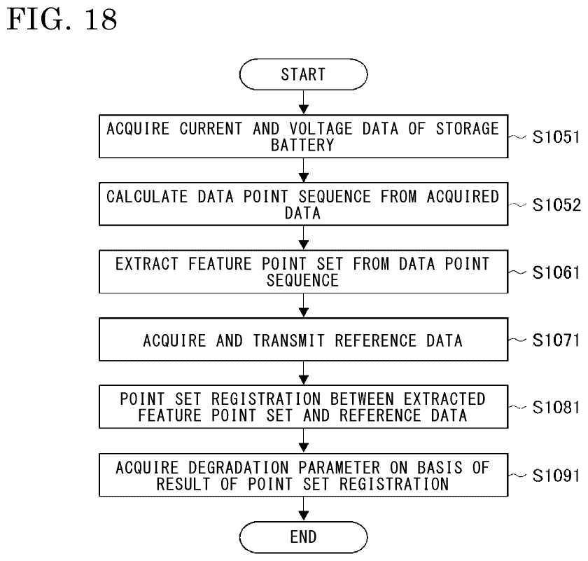

Next, a procedure of processing performed through a storage battery diagnosis method according to embodiment 1 will be described with reference to FIG. 18. FIG. 18 is a flowchart showing an example of the procedure of processing performed through the storage battery diagnosis method according to embodiment 1.

First, the data point sequence generation unit 5 acquires time-series data of current and voltage on the basis of a detected current acquired from the current detection device 3 and a detected voltage acquired from the voltage detection device 4 (step S1051).

The data point sequence generation unit 5 calculates time-series data of capacity and voltage by using the acquired data. One piece of time-series data of a Z^{th}-order derivative voltage curve where Z represents a real number larger than 0 is calculated, or a plurality of pieces of the time-series data with Z being different thereamong are calculated (step S1052).

The feature point set extraction unit 6 extracts a feature point set from the data point sequence of the voltage and/or the Z^{th}-order derivative voltage acquired in step S1052 (step S1061). As already described, the feature point set includes an inflection point, a local extremum point, and a zero crossing point. However, the feature points are not limited thereto and may be, in some cases, all data points on the data point sequence acquired in the previous step.

The reference data provision unit 7 acquires and transmits reference data (step S1071). Here, the reference data may be one that has already been acquired.

The point set registration unit 8 performs point set registration on the extracted feature point set such that the feature point set is registered to a feature point set of the transmitted reference data, to match the point sets with each other and estimate a transformation parameter (step S1081).

The diagnosis unit 9 estimates a degradation parameter of the storage battery 2 on the basis of at least the transformation parameter estimated through the point set registration (step S1091). In addition, the diagnosis unit 9 may further estimate degradation parameters by using the reference data. In the present embodiment, the negative electrode parameter corresponds to the degradation parameter of the storage battery 2 estimated on the basis of the transformation parameter, and the positive electrode parameter and the resistance parameter correspond to the degradation parameters further estimated by using the reference data.

The sequence of the processing shown in FIG. 18 is merely an example, and no limitation to this sequence is made .

### Summary of Characteristics and Advantageous Effects of Present Disclosure (Including Other Embodiments)

In addition to descriptions of the above embodiment, another embodiment and advantageous effects will be complementarily described in relation to each characteristic of the present disclosure.

### Characteristic 1

In the above embodiment 1, descriptions have been given on the basis of derivative curves. However, at least a part of the problem of diagnosis of the performance of a storage battery and/or estimation of internal states such as a capacity may be reduced to the problem of point set registration with respect to a Z^{th}-order derivative/integral curve such as a Z^{th}-order derivative/integral voltage curve or a Z^{th}-order derivative/integral capacity curve calculated through differentiation/integration (differentiation or integration) based on a real number Z. Then, through the point set registration technique, a data point sequence of the target storage battery is registered to a reference data point sequence. By performing the point set registration between the data point sequences, the point sets are matched with each other and a transformation parameter is estimated. Then, a storage battery parameter for diagnosis of the performance of the storage battery and/or estimation of internal states such as a capacity is calculated on the basis of the estimated transformation parameter.

The capacity may be one normalized relative to the full charge capacity of a certain storage battery at a certain time point, and the capacity normalized relative to the full charge capacity of the storage battery itself at said time is called a charging rate or a state of charge.

Since Z is any real number, differentiation/integration based on a real number Z means calculation performed through differentiation in the case of z>0, the voltage curve itself in the case of Z=0, or integration in the case of Z<0. Meanwhile, in a case where Z is not an integer, the differentiation/integration means calculation performed through fractional differentiation or fractional integration.

A fractional integral having a base point “a” can be efficiently calculated with the following Cauchy's integral formula.

$$\begin{matrix}[ Mathematical 19 ] & \\ {f}^{( - α )} ( x ) = \frac{1}{Γ ( α )} {\int }_{a}^{x} {( x - t )}^{α - 1} f ( t ) d t & ( 18 )\end{matrix}$$

In ordinary integration of an integer order as well, calculation can be performed with the same formula. Use of Cauchy's integral formula leads to efficiency in that a value is obtained by performing one time of integration calculation according to Cauchy's integral formula without repeating integration calculation n times in numerical calculation of n^{th}-order integration as well.

In the case of an α^{th}-order fractional derivative, there are several definitions. For example, if α is rewritten as α=n_{α}−β by using a natural number n_{α} and a real number β (0<β<1), calculation can be performed as follows.

$$\begin{matrix}[ Mathematical 20 ] & \\ {f}^{α} ( x ) = \frac{1}{Γ ( β )} {\int }_{a}^{x} {( x - t )}^{β - 1} {f}^{{n}_{α}} ( τ ) dt & ( 19 )\end{matrix}$$

This is called a Caputo derivative. That is, an operation of performing β^{th}-order integration (fractional integration) on a curve obtained through n_{α}^{th}-order differentiation (integer-order differentiation) only has to be performed.

For a formulation method and a calculation method of fractional differentiation/integration, knowledge of publicly-known fractional calculus can be utilized. For numerical integration as well, a publicly-known method may be employed. The Z^{th}-order derivative/integral curve may be either a Z^{th}-order derivative/integral voltage curve obtained by differentiating a voltage with a capacity, or a Z^{th}-order derivative/integral capacity curve obtained by differentiating a capacity with a voltage. Also, the horizontal axis may indicate capacity, voltage, or time. Although the horizontal axis of the Z^{th}-order derivative/integral voltage curve indicates capacity and the horizontal axis of the Z^{th}-order derivative/integral capacity curve indicates voltage, no limitation thereto is made.

As described with reference to FIG. 3, the voltage curve of the storage battery is a curve obtained by synthesis of a positive electrode potential curve and a negative electrode potential curve, and thus enlargement/reduction and deviation of the voltage curve include influences of degradation of both positive and negative electrodes.

However, degradation of one of the electrodes sometimes appears dominantly in the voltage curve, or influences of degradation of both electrodes sometimes similarly appear in the voltage curve. Alternatively, if focus is placed on a specific region (e.g., a region in which fluctuation of one of the electrodes is relatively great, or the like) of the voltage curve, influence of the potential curve of the one electrode sometimes appears dominantly. In such a case, even if merely point set registration between voltage curves of storage batteries is performed, a transformation parameter obtained through the point set registration and a value calculated from the transformation parameter can be parameters that accurately represent degradation of the storage battery.

Meanwhile, high-order differentiation or high-order integration makes it possible to also extract fluctuations of the potential curve of one of the electrodes. For example, in the case of a storage battery having a gentle positive electrode potential curve and a steep negative electrode potential curve as described with reference to FIG. 4 and FIG. 5, a high-frequency component can be extracted from the negative electrode potential curve through high-order differentiation, and in contrast, a low-frequency component can be extracted from the positive electrode potential curve through high-order integration. If a transformation parameter is obtained through point set registration after differential/integral calculation is thus performed, the parameter having been thus obtained corresponds to a parameter of the positive electrode or the negative electrode.

Examples of advantages obtained by solving the point set registration problem include the advantage that existing proven techniques such as ICP and CPD are applicable. In addition, in the case of an approach that involves comparison between point sets, acquisition or creation of a model of a storage battery and/or an electrode becomes entirely or partially unnecessary. Presence of a process of creating a model during a diagnosis gives rise to the risk that, owing to an error between a model and data or the like, modeling fails, or an unreliable diagnosis result is obtained. Meanwhile, the present approach is directly applicable as long as given data point sets are mutually resampled as appropriate.

### Characteristic 2

When a data point sequence of a target storage battery is registered to a reference data point sequence through the point set registration technique, point set registration between Z_D^{th}-order derivative curves to be subjected to point set registration or point set registration between Z_I^{th}-order integral curves to be subjected to point set registration may be performed (Z_D and Z_I are variables different from each other and are real numbers larger than 0). In general, differentiation leads to attenuation of a low-frequency component and amplification of a high-frequency component, and meanwhile, integration leads to attenuation of a high-frequency component and amplification of a low-frequency component. Further, this tendency becomes more prominent as the order of differentiation/integration becomes higher. Therefore, in estimation of a storage battery parameter as well, the easiness of the estimation according to the type of the storage battery parameter differs between a Z_D^{th}-order derivative curve and a Z_I^{th}-order integral curve. Considering this, point set registration is performed between a Z_D^{th}-order derivative curve of a data point sequence of a target storage battery and a reference Z_D^{th}-order derivative curve of a reference data point sequence, or between a Z_D^{th}-order integral curve of the data point sequence of the target storage battery and a reference Z_I^{th}-order integral curve of the reference data point sequence, and an estimation parameter is acquired from the result of each point set registration. Consequently, more storage battery parameters can be estimated, and the storage battery parameters can be more accurately estimated.

The reference data point sequence to be used may be a data point sequence of the storage battery or a data point sequence of an electrode.

The purpose of using the terms “Z_D^{th}-order” and

“Z_I^{th}-order” in the above description is to clarify that they are different variables. The reason for the clarification is that use of the term “Z^{th}-order” might lead to interpretation as being in the sense that the number of times is the same between the derivative curve and the integral curve (for example, if Z is 3.2, the term might lead to interpretation as being a 3.2^{th}-order derivative curve and a 3.2^{th}-order integral curve), and this interpretation needs to be prevented. In a case where it is unnecessary to clarify that they are different variables, the derivative curve and the integral curve will be written with the term “Z^{th}-order” (Z is a real number larger than 0).

### Characteristic 3

A parameter of one of the electrodes is estimated from the result of point set registration between the Z_D^{th}-order derivative curves, and a parameter of the other electrode is estimated from the result of point set registration between the Z_I^{th}-order integral curves. As shown in FIGS. 4 and 5, the dominant frequency component of a potential curve is a high frequency or a low frequency depending on the material of the electrode. Thus, if it is interpreted that electrode potential curves that differ between the Z_D^{th}-order derivative curves and the Z_I^{th}-order integral curves are emphasized and extracted, a corresponding electrode parameter can be estimated from the result of each point set registration. By taking such an approach, parameters can be separately estimated for the respective electrodes, more storage battery parameters can be estimated, and the storage battery parameters can be more accurately estimated.

### Characteristic 4

Data point sequences are not directly used, but feature point sets are extracted from the data point sequences, and point set registration between the feature point sets is performed. By using the feature point sets, calculation cost for point set registration decreases. In addition, by appropriately extracting the feature point sets, the robustness of point set registration is improved. Further, in comparison with the conventional derivative voltage analysis method, point set registration is performed, and thus, even if some of feature points vanish or the positions and/or the heights of the feature points are changed, robust and highly accurate point set registration that is not prone to be influenced by vanishment and/or fluctuation of said some of the feature points can be automatically performed by performing comprehensive registration with use of a plurality of or all of the feature points.

### Characteristic 5

The present disclosure is characterized by extracting a feature point set including at least two of a concave inflection point, a convex inflection point, a local maximum point, a local minimum point, a positive zero crossing point, and a negative zero crossing point. In the derivative voltage analysis method, a degradation diagnosis is performed according to the distance between two peaks (local maximum points) on a derivative voltage curve. Meanwhile, in the present disclosure, point set registration is performed by using at least two feature points among a total of six types of feature points also including feature points other than a local maximum point. Consequently, even in the case of a data point sequence that is obtained at the time of partial charging and on which two or more local maximum points are not present, a slight change in the curve shape can be extracted as a feature point set, and a diagnosis can be performed through point set registration.

### Characteristic 6

If characteristic 5 is more specifically expressed, point set registration is collectively performed by using two or more mutually different Z^{th}-order derivative curves. By doing so, the robustness of point set registration is improved. For example, even in a case where some of feature points fail to be detected on a first-order derivative curve, and meanwhile, some of feature points are erroneously detected owing to influence of an error at a location at which said feature points do not actually exist, if said feature points are appropriately extracted on a second-order derivative curve, influence of detection failure is less likely to be inflicted since both curves are used. In addition, in a case where wrong matching between point sets has been performed, errors occur in both of the two curves, and thus this occurrence is considered to make it less likely to lead to a failure in which convergence to wrong matching between the point sets occurs owing to incidental decrease in error.

### Characteristic 7

Feature point sets extracted on two or more respective derivative curves are mutually compared to perform checking as to coincidence, whereby the robustness of feature point extraction is increased. As a result, the accuracies of point set registration and diagnosis are increased.

Specifically, it is possible to utilize, for example, the relationship in which the positions of a concave inflection point and a convex inflection point on a Z_D^{th}-order derivative curve respectively correspond to the positions of a local maximum point and a local minimum point on a Z_D+1^{th}-order derivative curve, as in FIG. 8.

For example, if no local minimum point is detected on the Z_D+1^{th}-order derivative curve despite the fact that a convex inflection point is detected on the Z_D^{th}-order derivative curve, either of the detections is found to be an erroneous detection. Therefore, an erroneous detection can be corrected after being ascertained through: an attempt to perform detection again with a different detection method or a different setting parameter for detection; checking as to whether or not a positive zero crossing point is detected on a Z_D+2^{th}-order derivative curve; or the like.

### Characteristic 8

Similar to characteristic 7, checking and correction are performed as to coincidence between feature point sets extracted on two or more mutually different Z^{th}-order derivative curves. Meanwhile, a characteristic that an electrode potential curve of the storage battery undergoes a sigmoidal potential change owing to a phase change is utilized at this time. In general, a sigmoid curve has the following characteristic. That is, as in FIG. 8, if a sigmoid curve is differentiated, a peak curve is obtained, and, if the peak curve is further differentiated, a curve having one local maximum point and one local minimum point is obtained. Subsequently, each time differentiation is performed, the number of the local extremum points is increased by one, and the number of the inflection points is increased by two.

Therefore, the number of each type of feature points when the sigmoid curve is subjected to N^{th}-order differentiation where N represents an integer not smaller than 0, is ascertained. Also, in a case where actual electrode potential curves and a voltage curve of the storage battery expressed with synthesis of the curves involve a plurality of phase changes, expression can be performed by superimposition of the sigmoid curves. Judging from this, in the voltage curve of the storage battery, among the above-described types of feature points in the embodiment, a concave inflection point is considered to exist at a phase change center position, and a convex inflection point is considered to exist between one phase change and another phase change. In this manner, the storage battery voltage curve can be expressed as the sum of the sigmoid curves, and checking as to coincidence between the results of feature point extraction can be performed on the basis of the number and the types of the feature points on each of the sigmoid curve and the derivative curves thereof.

### Characteristic 9

The reference data provision unit 7 does not provide a raw reference data point sequence, but provides a smoothed reference data point sequence. Ordinarily, the strength of smoothing for the purpose of decreasing a measurement error and a quantization error is limited to minimum necessary strength, and such smoothing is performed so as to save the original curve shape excluding the errors, as much as possible. However, the present characteristic involves increasing the strength of smoothing to intentionally make the curve shape of the reference data point sequence gentle, whereby the curve shape is made similar to the curve shape of the data point sequence of the degraded storage battery being subjected to the diagnosis. As a result, the number of feature points to be extracted decreases and approximates to the number of feature points to be extracted from the data point sequence of the storage battery being subjected to the diagnosis.

In general, there is a tendency that, as a storage battery further degrades so that the voltage curve thereof changes accordingly, the curve shape thereof becomes gentler, and, in association with this, more feature points such as a local extremum point vanish. Therefore, as degradation of the degraded cell further progresses, the number of feature points on Z^{th}-order derivative/integral curves of the voltage and the electrode potentials is considered to further differ between the new cell and the degraded cell. Meanwhile, considering point set registration, if the number of the feature points differs therebetween, the number of combinations with which point sets can be matched with each other increases, and thus there is an increased risk that appropriate matching fails. Therefore, if possible, unnecessary feature points are desirably removed in advance. Also, in a case where point set registration is performed between data point sequences instead of the feature point sets, a larger difference between the curve shapes causes failure of the registration, and thus the curve shapes are desirably similar to each other.

The reason why the electrode potential curves become gentle owing to degradation is considered to be because, between a large number of particles existing in the electrodes, the extent of degradation differs or the resistance increases owing to degradation so that it becomes easy for a distribution to be generated with respect to the SOC per particle during charging/discharging. If a distribution is generated between the particles, the timings of potential changes due to phase changes of the respective particles differ from one another. Thus, each electrode potential is considered to have a value obtained by averaging the distribution of these different potentials. Such a difference in the extent of internal degradation and an ion distribution are difficult to exactly reproduce, but can be approximately expressed by smoothing a curve that is obtained in the case of a new cell or the like and that serves as a reference. Owing to smoothing performed with an appropriate strength and through an appropriate method, feature points derived from slight shape changes detected only from the reference data point sequence come to be no longer detected, whereby feature points common to a curve of the degraded cell are expected to be selectively extracted from a curve of the reference storage battery.

For smoothing, a method such as one described as a method for eliminating noise may be employed, for example. The strength of smoothing can be ordinarily adjusted through, for example, setting of a hyperparameter in each method. For example, in the case of using a moving average filter, the number of smoothing points only has to be increased in order to increase the strength of smoothing. Meanwhile, for example, in the case of using a Gaussian filter, not only the number of smoothing points but also a dispersion parameter can be adjusted in order to increase the strength of smoothing.

### Characteristic 10

Characteristic 9 is more specifically expressed. The strength of smoothing is adjusted such that the number of points of a feature point set to be extracted decreases through smoothing of a reference data point sequence. Whether or not the curve shape has become sufficiently gentle can be checked according to, as an index, whether or not the number of points of the feature point set to be extracted has decreased, or the extent of the decrease. In particular, in the case of performing point set registration on feature point sets, the present characteristic has the significance of decreasing the above unnecessary feature points, and thus has an advantageous effect also in performing highly accurate point set registration.

### Characteristic 11

Specification is performed such that an enlargement/reduction parameter and a translation parameter are included as transformation parameters for use in point set registration. In this state, electrode parameters including a full charge capacity retention rate of at least one of the electrodes and including a capacity deviation of the electrode or a capacity error of the storage battery, are estimated from transformation parameters estimated as a result of point set registration.

As is obvious from comparison between expression (9) and expression (11), an electrode parameter in an equation regarding an electrode potential curve of a storage battery and a transformation parameter in point set registration are in a clear correspondence relationship. Therefore, regarding Z^{th}-order derivative/integral curves, in a case where the curve shape of one of the electrodes is dominant as compared with the curve shape of the other electrode, a parameter of the one electrode can be calculated from a transformation parameter obtained by performing point set registration on the Z^{th}-order derivative/integral curves. In this case, solving of the problem of point set registration and the problem, regarding the storage battery, of estimating an electrode parameter are directly linked to each other.

### Characteristic 12

The details of characteristic 11 are more specifically expressed. It is assumed that: one of the electrodes is a negative electrode and is made from graphite; and second-order derivative voltage curves are included as Z^{th}-order derivative/integral curves. In the case where the negative electrode is made from graphite, a potential curve having a fluctuation steeper than those of many positive electrode materials is obtained, and, on the second-order derivative voltage curves, a component derived from the positive electrode is attenuated and a component derived from the negative electrode is dominant, whereby the second-order derivative curves and feature point sets extracted therefrom are mainly derived from the negative electrode. Therefore, transformation parameters including an enlargement/reduction parameter and a translation parameter estimated as a result of point set registration on the second-order derivative curves or the feature point sets correspond to the full charge capacity retention rate and the capacity deviation of graphite of the negative electrode.

### Characteristic 13

The storage battery diagnosis device estimates parameters of both electrodes. Specifically, a potential curve of one of the electrodes is generated first on the basis of: a reference electrode potential curve regarding the one electrode; and a parameter of the one electrode calculated on the basis of the result of point set registration. Then, the electrode potential curve of the one electrode is subtracted from a voltage curve of the storage battery, whereby a potential curve of the other electrode is calculated. Therefore, an electrode parameter of the other electrode can also be calculated as follows. That is, as described in the above embodiment, the potential curve of the other electrode and a reference potential curve of the other electrode are compared with each other, and the electrode parameter is estimated such that the error therebetween becomes small (minimum). Even in a case where no reference electrode potential curve of the other electrode is retained, a reference electrode potential curve of the other electrode can be calculated by subtracting a reference potential curve of the one electrode from a reference voltage curve of the storage battery.

By doing so, the electrode parameters of both electrodes can be estimated, and a more elaborate degradation diagnosis can be performed. In addition, parameters of the respective electrodes are separately estimated, and accordingly, the number of parameters becomes smaller than that in a method for collectively estimating electrode parameters of both electrodes. Consequently, a calculation burden is expected to be lessened, and the robustness and the accuracy of calculation are expected to be improved.

### Characteristic 14

ICP is employed for point set registration. The ICP is a highly reliable technique that involves a simple approach and that is employed in various fields.

### Characteristic 15

In the ICP, point set matching is separately performed on each type of feature point. By doing so, point set matching can be performed more robustly.

### Characteristic 16

Characteristic 15 is more specifically expressed, and one-dimensional ICP in which only an error in the horizontal axis is considered is employed for feature point sets. Details of the one-dimensional ICP is as described in embodiment 1, and the one-dimensional ICP has advantages such as: the advantage that influence of a storage battery voltage curve becoming gentler owing to degradation is less likely to be inflicted; and the advantage that transformation parameter estimation can be reduced to the linear least-squares method. Through reduction to the linear least-squares method, repetitive calculation having been necessary for nonlinear optimization becomes unnecessary, and a unique solution that is not dependent on an initial value is obtained in the relevant step. Therefore, parameter tuning becomes unnecessary, and the speed of calculation processing is increased.

### Characteristic 17

CPD is employed for point set registration. In the CPD, nonlinear transformations such as a transformation involving distortion of the positional relationship between point sets can also be flexibly performed. In this sense, the CPD has the advantage that point set registration can be flexibly performed even between data point sequences, of storage batteries, having curves that become gentle owing to degradation.

With more specific description, parameters including an enlargement/reduction parameter and a translation parameter are estimated so as to decrease the difference between the feature point set and the reference feature point set on the basis of the result of matching between the point sets performed through point set registration according to the CPD. Consequently, an electrode parameter of at least one of the electrodes is estimated. By doing so, even in a case where an enlargement/reduction parameter and a translation parameter are not used in the CPD or the CPD involves nonlinear transformation, such a parameter can be acquired. Here, matching between the point sets has been achieved through the CPD, and thus parameters including an enlargement/reduction parameter and a translation parameter may be estimated through a nonlinear optimization method or the like such that the error between corresponding points or feature points becomes minimum.

### Storage Battery System

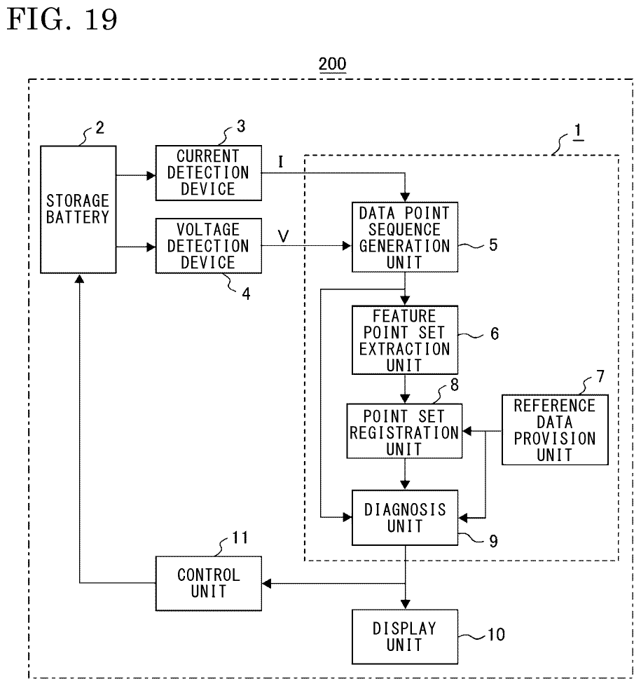

FIG. 19 shows an example of a storage battery system 200 in which the storage battery diagnosis device 1 having the above characteristics 1 to 17 is used for stationary installation in a vehicle, a domicile, or the like in which the storage battery 2 is used. The storage battery system 200 includes: a display device 10 which displays a diagnosis result from the above storage battery diagnosis device 1; and a control unit 11 which controls the storage battery 2 on the basis of the diagnosis result. The control unit 11 predicts the performance and the lifespan of the storage battery 2 on the basis of degradation information about the storage battery 2 estimated by the storage battery diagnosis device 1, and displays a replacement timing for the storage battery 2 on the display device 10. Also, in the case of the vehicle, display may be performed so as to prompt the driver to drive the vehicle in a manner that is based on the lifespan and the performance of the storage battery.

In the same manner as that shown in FIG. 2, the control unit 11 is composed of a processor and a storage device, and the storage device includes a volatile storage device such as a random access memory and a nonvolatile auxiliary storage device such as a flash memory. Alternatively, the storage device may include, as the auxiliary storage device, a hard disk instead of a flash memory. The processor executes a program inputted from the storage device, thereby performing the above control on the basis of a result from the storage battery diagnosis device 1. In this case, the program is inputted from the auxiliary storage device via the volatile storage device to the processor. Further, the processor may output data such as a calculation result to the volatile storage device of the storage device or may save the data via the volatile storage device into the auxiliary storage device.

Although the disclosure is described above in terms of an exemplary embodiment, it should be understood that the various features, aspects, and functionality described in the embodiment are not limited in their applicability to the particular embodiment with which they are described, but instead can be applied alone or in various combinations to the embodiment of the disclosure.

It is therefore understood that numerous modifications which have not been exemplified can be devised without departing from the scope of the specification of the present disclosure. For example, at least one of the constituent components may be modified, added, or eliminated.

### DESCRIPTION OF THE REFERENCE CHARACTERS

1 storage battery diagnosis device
2 storage battery
3 current detection device
4 voltage detection device
5 data point sequence generation unit
6 feature point set extraction unit
7 reference data provision unit
8 point set registration unit
9 diagnosis unit
20 controller
20a processor
20b storage device
100 storage battery diagnosis system
200 storage battery system

1. A storage battery diagnosis device comprising:
a data point sequence generator which generates, on the basis of a current of a storage battery detected by a current detection device and a voltage of the storage battery detected by a voltage detection device, a data point sequence including a Z^{th}-order derivative/integral curve expressed with a Z^{th}-order derivative/integral voltage or a Z^{th}-order derivative/integral capacity where Z represents a real number;
a reference data provider which provides, as a reference, a reference data point sequence of the storage battery or an electrode;
a point set registrator which performs point set registration between the reference data point sequence and the data point sequence generated by the data point sequence generation unit;
a diagnosis circuitry which estimates a parameter indicating a state of degradation of the storage battery or the electrode on the basis of a result from the point set registrator;
a feature point set extractor which extracts a feature point set from the data point sequence and extracts a reference feature point set from the reference data point sequence, wherein
the point set registrator performs point set registration between the feature point set and the reference feature point set; and
wherein
each of the feature point set and the reference feature point set extracted by the feature point set extractor includes at least two feature points among a concave inflection point, a convex inflection point, a local maximum point, a local minimum point, a positive zero crossing point, and a negative zero crossing point.

2-5. (canceled)

6. The storage battery diagnosis device according to claim 1, wherein
in a case of generating a data point sequence including a Z_D^{th}-order derivative curve, derivative curves of two or more mutually different orders are included.

7. The storage battery diagnosis device according to claim 1, wherein
in a case of generating a data point sequence including a Z_D^{th}-order derivative curve, the feature point sets or the reference feature point sets extracted by the feature point set extractor are such that positions of the feature point sets or the reference feature point sets are caused to coincide with each other between derivative curves of two or more mutually different orders.

8. The storage battery diagnosis device according to claim 1, wherein
in a case of generating a data point sequence including a Z_D^{th}-order derivative curve, the feature point sets or the reference feature point sets extracted by the feature point set extractor are such that positions of the feature point sets or the reference feature point sets are caused to coincide with each other between two or more different Z_D^{th}-order derivative curves on the basis of a sigmoidal potential change, due to a phase change, in an electrode potential curve of the storage battery.

9. The storage battery diagnosis device according to claim 1, wherein
the reference data provision unit smooths the reference data point sequence.

10. The storage battery diagnosis device according to claim 1, wherein
the reference data provider smooths the reference data point sequence and adjusts a strength of smoothing such that the number of feature points in a reference feature point set extracted from the smoothed reference data point sequence by the feature point set extractor is smaller than the number of feature points in the reference feature point set extracted from the reference data point sequence by the feature point set extractor.

11. The storage battery diagnosis device according to claim 1, wherein
the point set registrator calculates transformation parameters including an enlargement/reduction parameter and a translation parameter, and
the diagnosis circuitry calculates, on the basis of the transformation parameters, electrode parameters including a full charge capacity retention rate of the electrode and including a capacity deviation of the electrode or a capacity error of the storage battery.

12. The storage battery diagnosis device according to claim 1, wherein
the Z^{th}-order derivative/integral curve generated by the data point sequence generator includes a Z_D^{th}-order derivative curve and a Z_I^{th}-order integral curve,
the reference data point sequence from the reference data provider includes at least parts of a reference Z_D^{th}-order derivative curve and a reference Z_I^{th}-order integral curve, and
the point set registrator
performs point set registration between data point sequences which are the Z_D^{th}-order derivative curve and the reference Z_D^{th}-order derivative curve, and
performs point set registration between data point sequences which are the Z_I^{th}-order integral curve and the reference Z_I^{th}-order integral curve,
where Z_D and Z_I each represent a real number larger than 0; and
the point set registrator calculates transformation parameters including an enlargement/reduction parameter and a translation parameter,
the diagnosis circuitry calculates, on the basis of the transformation parameters, electrode parameters including a full charge capacity retention rate of the electrode and including a capacity deviation of the electrode or a capacity error of the storage battery,
in a case of generating a data point sequence including the Z_D^{th}-order derivative curve, the Z_D^{th}-order derivative curve is a second-order derivative curve, and,
out of the electrodes, a negative electrode is made from graphite.

13. The storage battery diagnosis device according to claim 11, wherein
the reference data provider provides a reference data point sequence of the storage battery and a reference data point sequence of at least one electrode out of a positive electrode and a negative electrode of the storage battery,
the diagnosis circuitry
generates an electrode potential curve of the one electrode on the basis of an electrode parameter and the reference data point sequence of the one electrode,
subtracts the electrode potential curve from the reference data point sequence of the storage battery, to generate an electrode potential curve of another one of the electrodes,
compares the electrode potential curve of the other electrode and a reference data point sequence of the other electrode with each other, and
obtains an electrode parameter of the other electrode, and,
in a case where no reference data point sequence of the other electrode is provided from the reference data provider, the diagnosis circuitry calculates a reference data point sequence of the other electrode on the basis of a difference between the reference data point sequence of the storage battery and the reference data point sequence of the one electrode.

14. The storage battery diagnosis device according to claim 1, wherein
the point set registrator performs point set registration through ICP.

15. The storage battery diagnosis device according to claim 1, wherein
the point set registrator performs point set registration through ICP and separately performs point set matching through the ICP on each type of feature point in the feature point set.

16. The storage battery diagnosis device according to claim 14, wherein
the ICP is one-dimensional ICP for a feature point set.

17. The storage battery diagnosis device according to claim 1, wherein
the point set registrator performs point set registration through CPD.

18. A storage battery system comprising:
the storage battery diagnosis device according to claim 1;
a display device which displays an output from the storage battery diagnosis device; and
a controller which controls the storage battery on the basis of the output from the storage battery diagnosis device.
